(19) United States
(12) Patent Application Publication
(10) Pub. No.: US 2025/0204047 A1
(43) Pub. Date: Jun. 19, 2025

(54) DISPLAY PANEL, ARRAY SUBSTRATE AND METHOD FOR MANUFACTURING ARRAY SUBSTRATE

(71) Applicants: Beijing BOE Display Technology Co., Ltd., Beijing (CN); BOE Technology Group Co., Ltd., Beijing (CN)

(72) Inventors: Jinchao BAI, Beijing (CN); Bo LIU, Beijing (CN); Jing LIU, Beijing (CN); Hui GUO, Beijing (CN); Xiangqian DING, Beijing (CN); Yanxin JI, Beijing (CN); Yue LIU, Beijing (CN); Haipeng LIU, Beijing (CN)

(21) Appl. No.: 18/849,776

(22) PCT Filed: Aug. 30, 2022
(86) PCT No.: PCT/CN2022/115817

§ 371 Date: Sep. 23, 2024

(30) Foreign Application Priority Data
Mar. 31, 2022 (WO) PCT/CN2022/084485

(51) Int. Cl. H10D 86/40; G02F 1/1368

(52) U.S. Cl. CPC H10D 86/451; G02F 1/1368; H10D 86/443

(57) ABSTRACT

The present disclosure provides a display panel, an array substrate and a method for manufacturing the array substrate, and belongs to the field of display technology. The array substrate includes a base substrate, a driving circuit layer, an organic film layer and a conductive layer which are sequentially stacked; at least part of the organic film layer in a peripheral area is provided with a blocking groove; the array substrate further includes a first protrusion, and at least part of the first protrusion is located in the blocking groove; and at least part of the first protrusion is in contact with the organic film layer; the conductive layer comprises a signal line crossing an edge of the blocking groove, and an edge of the signal line is at least partially overlapped with the first protrusion.

### TECHNICAL FIELD

The present disclosure relates to the field of display technology, and particularly relates to a display substrate, an array substrate and a method for manufacturing an array substrate.

### BACKGROUND

In the display panel, an organic film layer has the characteristics of small dielectric constant, strong smoothness and the like, can reduce the power consumption of the display panel and is beneficial to improving the display contrast, so that the organic film layer is more and more widely applied to the display panel. Because the organic film layer has the characteristics of easy water absorption, the organic film layer needs to be provided with a blocking groove in a peripheral area of the display panel. However, when a conductive layer is formed on the organic film layer, short-circuit defects of the display panel in the blocking groove are frequently occurred.

It is noted that the information disclosed in the above background part is only for enhancement of understanding of the background of the present disclosure and therefore may include information that does not constitute prior art that is already known to a person of ordinary skill in the art.

### SUMMARY

The present disclosure is directed to at least one of the technical problems in the prior art, and provides a display panel, an array substrate and a method for manufacturing the array substrate.

In a first aspect, an embodiment of the present disclosure provides an array substrate, which includes a base substrate, a driving circuit layer, an organic film layer and a conductive layer which are sequentially stacked; and at least part of the organic film layer in a peripheral area is provided with a blocking groove;
the array substrate further includes a first protrusion, and at least part of the first protrusion is located in the blocking groove; and at least part of the first protrusion is in contact with the organic film layer; the conductive layer includes a signal line crossing edges of the blocking groove, and an edge of the signal line is at least partially overlapped with the first protrusion.

In some implementations, in at least a partial region of the blocking groove, two edges of the blocking groove each are provided with a plurality of first protrusions;
for the first protrusions on a same edge of the blocking groove, an orthographic projection of a gap between two adjacent first protrusions on the base substrate is a first pattern; in a direction that a display area points to the peripheral area, a width of a portion of the first pattern close to the display area is not smaller than a width of a portion of the first pattern away from the display area.

In some implementations, the first pattern includes an isosceles triangle or an isosceles trapezoid.

In some implementations, for the first protrusions provided on a same edge of the blocking groove, a maximum pitch between two adjacent first protrusions is a, a height of the first pattern is b, and b≥3a.

In some implementations, the first protrusions provided on two edges of the blocking groove are in a one-to-one correspondence, and a distance is provided between two first protrusions corresponding to each other and respectively provided on the two edges of the blocking groove.

In some implementations, two edges of a single signal line are respectively overlapped with two adjacent first protrusions, and the signal line covers a gap between the two adjacent first protrusions.

In some implementations, for the first protrusions provided on a same edge of the blocking groove, an orthographic projection of each first protrusion on the base substrate is a second pattern, first patterns and second patterns are alternately arranged, and the first pattern is obtained by vertically inverting the second pattern.

In some implementations, orthographic projections of two edges of the signal line on the base substrate are respectively overlapped with orthographic projections of first central lines of two adjacent first protrusions on the base substrate; the first central line of the first protrusion is a straight line which is in the direction in which the display area points to the peripheral area and penetrates through a center of a position of the first protrusion at which the first protrusion is connected with the edge of the blocking groove.

In some implementations, in at least a partial region of the blocking groove, two edges of the blocking groove are respectively provided with a plurality of first protrusions;
two edges of a single signal line are respectively overlapped with two adjacent first protrusions, and the signal line is not overlapped with a gap between the two adjacent first protrusions.

In some implementations, the first protrusion and the organic film layer are formed a single piece.

In some implementations, a plurality of blocking grooves are provided, and at least part of the blocking grooves are sequentially arranged around the display area.

In some implementations, at least part of the blocking grooves are continuously arranged.

In some implementations, at least part of the blocking grooves includes a plurality of sub-grooves spaced apart from each other.

In some implementations, the driving circuit layer includes the first protrusion in the peripheral area of the array substrate; the first protrusion includes a first protruding metal block located in at least one of a source-drain metal layer or a gate layer and a first protruding insulation layer covering the first protruding metal block;
the organic film layer includes the blocking groove in the peripheral area, and a portion of the first protrusion is covered by the organic film layer and another portion of the first protrusion is exposed by the blocking groove.

In some implementations, in at least a partial region of the blocking groove, two edges of the blocking groove are respectively provided with a plurality of first protrusions;
two edges of a single signal line are respectively overlapped with two adjacent first protrusions, and the signal line covers a gap between the two adjacent first protrusions.

In some implementations, in at least a partial region of the blocking groove, two edges of the blocking groove are respectively provided with one first protrusion; the signal line and the first protrusions are intersected.

In some implementations, a plurality of first protrusions are provided in at least a partial region of the blocking groove; two ends of any one of the first protrusions are respectively covered by the organic film layer on two sides of the blocking groove; two edges of each of at least part of signal lines are respectively overlapped with two adjacent first protrusions, and the signal line covers a gap between the two adjacent first protrusions.

In some implementations, in at least a partial region of the blocking groove, one first protrusion is provided, and both sides of the first protrusion are covered by the organic film layer on both sides of the blocking groove; a portion of at least part of the signal lines at a bottom surface of the blocking groove is carried on the first protrusion.

In some implementations, the driving circuit layer includes a ground line in the peripheral area, and the ground line at least partially overlaps the blocking groove;
at least part of first protruding metal blocks is a part of the ground line.

In some implementations, the driving circuit layer includes a ground line in the peripheral area, and the ground line at least partially overlaps the blocking groove;
positions at which the signal line crosses the edges of the blocking groove are not overlapped with the ground line.

In some implementations, a dimension of a portion of the first protrusion covered by the organic film layer in a direction perpendicular to an extending direction in which the blocking groove extends is not less than 2 μm.

In some implementations, a height of the first protrusion protruding from the bottom of the blocking groove is not less than 10% of a depth of the blocking groove.

In a second aspect, an embodiment of the present disclosure provides a method for manufacturing an array substrate, including:
forming a driving circuit layer on a side of a base substrate;
sequentially forming an organic film layer and a conductive layer on a side of the driving circuit layer away from the base substrate; at least part of the organic film layer in the peripheral area is provided with a blocking groove;
the method further includes: forming a first protrusion; at least part of the first protrusion is located in the blocking groove; and at least part of the first protrusion is in contact with the organic film layer; the conductive layer includes a signal line crossing edge of the blocking groove, and an edge of the signal line is at least partially overlapped with the first protrusion.

In some implementations, in at least a partial region of the blocking groove, two edges of the blocking groove are respectively provided with a plurality of first protrusions;
for the first protrusions on a same edge of the blocking groove, an orthographic projection of a gap between two adjacent first protrusions on the base substrate is a first pattern; in a direction that a display area points to the peripheral area, a width of a portion of the first pattern close to the display area is not smaller than a width of a portion of the first pattern away from the display area.

In some implementations, the first pattern includes an isosceles triangle or an isosceles trapezoid.

In some implementations, for the first protrusions provided on a same edge of the blocking groove, a maximum pitch between two adjacent first protrusions is a, a height of the first pattern is b, and b≥3a.

In some implementations, the first protrusions provided on two edges of the blocking groove are in a one-to-one correspondence, and a distance is provided between two first protrusions corresponding to each other and respectively provided on the two edges of the blocking groove.

In some implementations, two edges of a single signal line are respectively overlapped with two adjacent first protrusions, and the signal line covers a gap between the two adjacent first protrusions.

In some implementations, for the first protrusions provided on a same edge of the blocking groove, an orthographic projection of each first protrusion on the base substrate is a second pattern, first patterns and second patterns are alternately arranged, and the first pattern is obtained by vertically inverting the second pattern.

In some implementations, orthographic projections of two edges of the signal line on the base substrate are respectively overlapped with orthographic projections of first central lines of two adjacent first protrusions on the base substrate; the first central line of the first protrusion is a straight line which is in the direction in which the display area points to the peripheral area and penetrates through a center of a position of the first protrusion at which the first protrusion is connected with the edge of the blocking groove.

In some implementations, in at least a partial region of the blocking groove, two edges of the blocking groove are respectively provided with a plurality of first protrusions;
two edges of a single signal line are respectively overlapped with two adjacent first protrusions, and the signal line is not overlapped with a gap between the two adjacent first protrusions.

In some implementations, the first protrusion and the organic film layer are formed in a single patterning process.

In some implementations, the driving circuit layer includes the first protrusion, the first protrusion includes a first protruding metal block located in at least one of a source-drain metal layer or a gate layer, and a first protruding insulation layer covering the first protruding metal block; a part of the first protrusion is covered by the organic film layer and the other part of the first protrusion is exposed by the blocking groove.

In some implementations, in at least a partial region of the blocking groove, two edges of the blocking groove are respectively provided with a plurality of first protrusions;
two edges of a single signal line are respectively overlapped with two adjacent first protrusions, and the signal line covers a gap between the two adjacent first protrusions.

In some implementations, in at least a partial region of the blocking groove, two edges of the blocking groove are respectively provided with one first protrusion; the signal line and the first protrusions are intersected.

In some implementations, a plurality of first protrusions are provided in at least a partial region of the blocking groove; two ends of any one of the first protrusions are respectively covered by the organic film layer on two sides of the blocking groove; two edges of each of at least part of signal lines are respectively overlapped with two adjacent first protrusions, and the signal line covers a gap between the two adjacent first protrusions.

In some implementations, in at least a partial region of the blocking groove, one first protrusion is provided, and both sides of the first protrusion are covered by the organic film layer on both sides of the blocking groove; a portion of at least part of the signal lines at a bottom surface of the blocking groove is carried on the first protrusion

In a third aspect, an embodiment of the present disclosure provides an array substrate, including a base substrate, a driving circuit layer, an organic film layer and a conductive layer which are sequentially stacked;
the driving circuit layer includes transfer lines in a peripheral area of the array substrate, and each transfer line is located in at least one of a source-drain metal layer or a gate layer;
the organic film layer is provided with a blocking groove and via holes exposing the transfer line in the peripheral area; at least part of the transfer lines crosses the blocking groove; the conductive layer comprises a signal line that is cut by edges of the blocking grooves, and two adjacent ends of portions of the signal line cut by the edges of the blocking groove are electrically connected by the transfer line; the signal line is connected with the transfer line through the via holes.

In some implementations, at least part of the signal lines crosses the blocking groove and both ends of the signal line are exposed by the via holes;
at least part of the signal lines are cut by the blocking groove, and two adjacent ends of the signal line are connected with two ends of the transfer line through the via holes respectively.

In some implementations, the conductive layer further includes, in the blocking groove, a conductive material at the edge of the blocking groove, and the conductive material is disconnected from the signal line.

In a fourth aspect, an embodiment of the present disclosure provides a method for manufacturing an array substrate, including:
forming a driving circuit layer on a side of a base substrate, where the driving circuit layer includes transfer lines in a peripheral area of the array substrate, and each transfer line is located in at least one of a source-drain metal layer and a gate layer;
sequentially forming an organic film layer and a conductive layer on a side of the driving circuit layer away from the base substrate; the organic film layer is provided with a blocking groove and via holes exposing the transfer line in the peripheral area; at least part of the transfer lines crosses the blocking groove; the conductive layer includes a signal line which is cut by edges of the blocking groove, and two adjacent ends of portions of the signal line cut by the edges of the blocking groove are electrically connected by the transfer line; the signal line is connected with the transfer line through the via holes.

In a fifth aspect, an embodiment of the present disclosure provides an array substrate, including a base substrate, a driving circuit layer, an organic film layer and a conductive layer which are sequentially stacked;
the driving circuit layer includes a second protrusion and a conductive structure in the peripheral area of the array substrate; the second protrusion includes a second protruding metal block located in the gate layer and a second protruding insulation layer covering the second protruding metal block; the conductive structure is located on a side of the second protrusion away from the base substrate and at least partially overlapped with the second protrusion;
the organic film layer is provided with a blocking groove in the peripheral area, and the second protrusion and the conductive structure are at least partially exposed by the blocking groove; and a portion of the conductive structure exposed by the blocking groove is completely carried on the second protrusion.

In some implementations, a gap is provided between an edge of the portion of the conductive structure exposed by the blocking groove and an edge of the second protrusion.

In some implementations, the conductive layer includes, in the blocking groove, a conductive material between the edge of the second protrusion and an edge of the blocking groove, the conductive material being disconnected from the conductive structure.

In a sixth aspect, an embodiment of the present disclosure provides a method for manufacturing an array substrate, including:
forming a driving circuit layer on a side of a base substrate, where the driving circuit layer includes a second protrusion and a conductive structure in a peripheral area of the array substrate; the second protrusion includes a second protruding metal block located in the gate layer and a second protruding insulation layer covering the second protruding metal block; the conductive structure is located on a side of the second protrusion away from the base substrate and at least partially overlapped with the second protrusion;
sequentially forming an organic film layer and a conductive layer on a side of the driving circuit layer away from the base substrate; the organic film layer is provided with a blocking groove in the peripheral area, and the second protrusion and the conductive structure are at least partially exposed by the blocking groove; and a portion of the conductive structure exposed by the blocking groove is completely carried on the second protrusion.

In some implementations, a gap is formed between an edge of the portion of the conductive structure exposed by the blocking groove and an edge of the second protrusion.

In a seventh aspect, an embodiment of the present disclosure provides a method for manufacturing an array substrate, including:
forming an organic film layer on a side of a base substrate, the organic film layer being provided with a blocking groove in a peripheral area;
forming a conductive material layer on a side of the organic film layer away from the base substrate, the conductive material layer covering the organic film layer and the blocking groove;
coating a photoresist on a side of the conductive material layer away from the base substrate, the photoresist covering the organic film layer and filling the blocking groove;
exposing the photoresist, where a focal plane of an exposure machine is below a surface of the photoresist; and
etching the conductive material layer, and then removing the photoresist.

In an eighth aspect, an embodiment of the present disclosure provides a display panel, including any one of the array substrates described above.

In some implementations, the display panel further includes a cover plate arranged opposite to and being to be combined with the array substrate, and a frame sealing adhesive arranged between the array substrate and the cover plate, the frame sealing adhesive covering the blocking groove;
the driving circuit layer includes a conductive line overlapped with the frame sealing adhesive in the peripheral area, and the conductive line is in a mesh.

### BRIEF DESCRIPTION OF DRAWINGS

FIG. 1 is a schematic cross-sectional diagram of a structure of a display panel according to an embodiment of the present disclosure.

FIG. 2-1 is a schematic top view of a structure of a display panel according to an embodiment of the disclosure.

FIG. 2-2 is a schematic top view of a structure of a display panel according to an embodiment of the disclosure.

FIG. 2-3 is a schematic top view of a structure of a display panel according to an embodiment of the disclosure.

FIG. 3 is a schematic cross-sectional diagram of a structure of an array substrate according to an embodiment of the present disclosure.

FIG. 4 is a schematic cross-sectional diagram of a structure of an array substrate according to an embodiment of the present disclosure.

FIG. 5 is a schematic diagram of a partial structure of an array substrate according to an embodiment of the present disclosure.

FIG. 6-1 is a schematic diagram illustrating a partial structure of an array substrate at a top corner according to an embodiment of the present disclosure.

FIG. 6-2 is a schematic diagram of a sub-structure of an electrode composite layer of an array substrate according to an embodiment of the present disclosure.

FIG. 7 is a schematic top view of a structure of an organic film layer and signal lines of an array substrate according to an embodiment of the present disclosure.

FIG. 8 is a schematic diagram of a structure in which an organic film layer is formed on a driving circuit layer in the related art.

FIG. 9 is a schematic diagram of a structure in which a conductive material layer is formed an organic film layer in the related art.

FIG. 10 is a schematic diagram of a structure in which a photoresist is coated in the related art.

FIG. 11 is a a schematic diagram of a structure in which a photoresist in a blocking groove is insufficiently exposed in the related art.

FIG. 12 is a schematic diagram of a structure in which a conductive material layer in a blocking groove is insufficiently etched in the related art.

FIG. 13 is a schematic flow chart illustrating a method for manufacturing an array substrate according to an embodiment of the present disclosure.

FIG. 14 is a schematic structural diagram of a driving circuit layer formed with a first protrusion according to an embodiment of the present disclosure.

FIG. 15 is a schematic diagram of a structure in which an organic film layer is formed on a side of a driving circuit layer away from a base substrate according to an embodiment of the present disclosure.

FIG. 16 is a schematic diagram of a structure in which a conductive material layer is formed on an organic film layer according to an embodiment of the present disclosure.

FIG. 17 is a schematic diagram of a structure in which a photoresist is coated on a side of a conductive material layer away from a base substrate according to an embodiment of the present disclosure.

FIG. 18 is a schematic structural diagram illustrating a relative positional relationship among a signal line, an organic film layer, and a first protrusion according to an embodiment of the present disclosure.

FIG. 19 is a cross-sectional view of the structure of FIG. 18 taken along M1-M1′.

FIG. 20 is a cross-sectional view of the structure of FIG. 18 taken along N1-N1′.

FIG. 21 is a schematic structural diagram illustrating a relative positional relationship among a signal line, an organic film layer, and a first protrusion according to an embodiment of the present disclosure.

FIG. 22 is a cross-sectional view of the structure of FIG. 21 taken along M2-M2′.

FIG. 23 is a cross-sectional view of the structure of FIG. 21 taken along N2-N2′.

FIG. 24 is a schematic structural diagram illustrating a relative positional relationship among a signal line, an organic film layer, and a first protrusion according to an embodiment of the present disclosure.

FIG. 25 is a cross-sectional view of the structure of FIG. 24 taken along M3-M3′.

FIG. 26 is a cross-sectional view of the structure of FIG. 24 taken along N3-N3′.

FIG. 27 is a schematic structural diagram illustrating a relative positional relationship among a signal line, an organic film layer, and a first protrusion according to an embodiment of the present disclosure.

FIG. 28 is a schematic cross-sectional view of the structure of FIG. 27 taken along M4-M4′.

FIG. 29 is a schematic cross-sectional view of the structure of FIG. 27 taken along N4-N4′.

FIG. 30 is a schematic flow chart illustrating a method for manufacturing an array substrate according to an embodiment of the present disclosure.

FIG. 31 is a schematic diagram of a structure in which an organic material layer is formed on a side of a driving circuit layer away from a base substrate according to an embodiment of the present disclosure.

FIG. 32 is a schematic diagram of a structure in which an organic material layer and a transfer insulation layer are patterned to form a via hole and a blocking groove according to an embodiment of the present disclosure.

FIG. 33 is a schematic structural diagram illustrating a relative positional relationship among a transfer line, an organic film layer, a blocking groove, and a via hole according to an embodiment of the present disclosure.

FIG. 34 is a schematic diagram of a structure in which a conductive material layer is formed on an organic film layer according to an embodiment of the present disclosure.

FIG. 35 is a schematic diagram of a structure in which a patterning process is performed on a conductive material layer according to an embodiment of the present disclosure.

FIG. 36 is a schematic structural diagram illustrating a relative positional relationship among a signal line, a transfer line (via line), an organic film layer, a blocking groove, and a via hole according to an embodiment of the present disclosure.

FIG. 37-1 is a schematic diagram illustrating a structure in which an organic film layer is formed on a driving circuit layer in the related art, where the driving circuit layer is provided with a conductive structure which is at least partially exposed by the blocking groove.

FIG. 37-2 is a schematic diagram of a structure in which a conductive material layer is formed on an organic film layer in the related art.

FIG. 38 is a schematic diagram of a structure in which a photoresist is coated in the related art.

FIG. 39 is a schematic diagram of a structure in which a photoresist in a blocking groove is insufficiently exposed in the related art.

FIG. 40 is a schematic diagram of a structure in which short-circuit occurs between conductive structures due to insufficient etching of a conductive material layer in a blocking groove in the related art.

FIG. 41 is a schematic flow chart illustrating a method for manufacturing an array substrate according to an embodiment of the present disclosure.

FIG. 42 is a schematic diagram of a structure in which a driving circuit layer having a second protrusion and a conductive structure, and an organic film layer are formed according to an embodiment of the present disclosure.

FIG. 43 is a schematic diagram of a structure in which a conductive material layer is formed on an organic film layer according to an embodiment of the present disclosure.

FIG. 44 is schematic diagram of a structure in which a photoresist is coated on a side of a conductive material layer away from a base substrate according to an embodiment of the present disclosure.

FIG. 45 is a schematic diagram of a structure in which a photoresist in a blocking groove is insufficiently exposed according to an embodiment of the present disclosure.

FIG. 46 is a schematic diagram of a structure in which a conductive material layer in a blocking groove is not etched sufficiently, where a residual conductive material is not connected to a conductive structure, according to an embodiment of the present disclosure.

FIG. 47 is a schematic diagram of a structure in which a focal plane is located on a surface of a photoresist during exposure in the related art.

FIG. 48 is a schematic flow chart illustrating a method for manufacturing an array substrate according to an embodiment of the present disclosure.

FIG. 49 is a schematic diagram of a structure in which a focal plane is located inside a photoresist during exposure according to an embodiment of the present disclosure.

FIG. 50 is a schematic diagram of a structure in which a focal plane is located on a lower surface of a photoresist during exposure according to an embodiment of the present disclosure.

FIG. 51 is a schematic diagram of a structure in which a focal plane

during exposure is below a lower surface of a photoresist according to an embodiment of the present disclosure.

FIG. 52 is a schematic flow chart illustrating a method for manufacturing an array substrate according to an embodiment of the present disclosure.

FIG. 53 is a schematic diagram of a structure in which a driving circuit layer is formed according to an embodiment of the disclosure.

FIG. 54 is a schematic diagram of a structure in which an organic film layer and a first protrusion are formed on a side of a driving circuit layer away from a base substrate according to an embodiment of the present disclosure.

FIG. 55 is a top view of an organic film layer and a first protrusion according to an embodiment of the present disclosure.

FIG. 56 is an enlarged view of a portion A of a structure of FIG. 55A.

FIG. 57 is a schematic diagram of a structure in which a conductive material layer is formed on an organic film layer according to an embodiment of the present disclosure.

FIG. 58 is a schematic diagram of a structure in which a photoresist is coated on a conductive material layer at a side away from a base substrate according to an embodiment of the present disclosure.

FIG. 59 is a schematic structural diagram illustrating a relative positional relationship among a signal line, an organic film layer, and a first protrusion according to an embodiment of the present disclosure.

FIG. 60 is a cross-sectional view of the structure of FIG. 59 taken along M5-M5′.

FIG. 61 is a cross-sectional view of the structure of FIG. 59 taken along N5-N5′.

FIG. 62 is a schematic structural diagram illustrating a relative positional relationship between a signal line and a first protrusion according to an embodiment of the present disclosure.

FIG. 63 is a schematic structural diagram illustrating a relative positional relationship between a signal line and a first protrusion according to an embodiment of the present disclosure.

### DETAIL DESCRIPTION OF EMBODIMENTS

In order to make the technical solutions of the present disclosure better understood, the present disclosure is further described in detail below with reference to the accompanying drawings and the detailed implementations.

Unless defined otherwise, technical or scientific terms used herein shall have the ordinary meaning as understood by one of ordinary skill in the art to which this disclosure belongs. The term “first”, “second” and the like in this disclosure is not intended to indicate any order, quantity, or importance, but rather is used to distinguish one element from another. Also, the term “a”, “an”, “the” or the like does not denote a limitation of quantity, but rather denotes the presence of at least one. The term “comprising/including”, “comprises/includes” or the like means that the element or item preceding the word includes the element or item listed after the word and its equivalent, but does not exclude other elements or items. The term “connected/connecting”, “coupled/coupling” or the like is not restricted to physical or mechanical connections, but may include electrical connections, whether direct or indirect. The term “Upper”, “lower”, “left”, “right”, and the like are used only to indicate relative positional relationships, and when the absolute position of the object being described is changed, the relative positional relationships may also be changed accordingly.

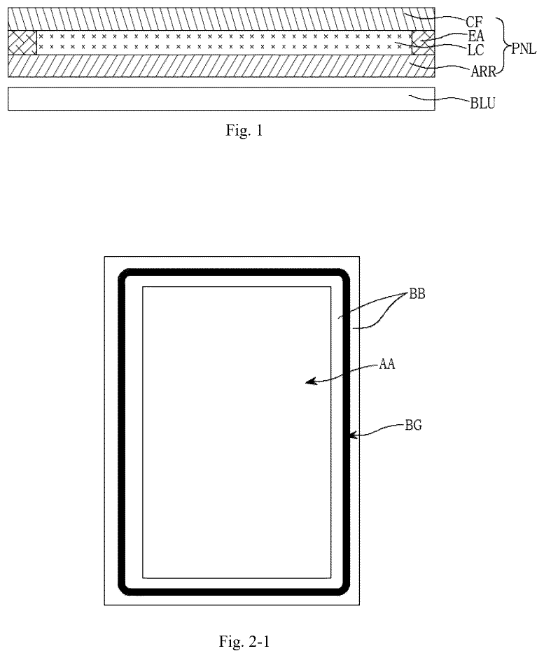

Referring to FIG. 1, from a perspective of a stacked structure, a display panel PNL in an embodiment of the present disclosure may include an array substrate ARR, an adhesive layer EA, and a cover plate CF sequentially stacked, which form a stacked structure. Referring to FIGS. 2-1 to 2-3, from a perspective of a planar structure, the array substrate ARR includes a display area AA for display and a peripheral area BB surrounding the display area AA. An organic film layer ORG is provided on the array substrate ARR, and has a blocking groove BG facing the cover plate CF at the peripheral area BB. The adhesive layer EA is filled in the blocking groove BG, so that, on one hand, an invasion path of moisture is blocked, and on the other hand, an adhesion between the adhesive layer EA and the array substrate ARR is enhanced.

Exemplarily, referring to FIG. 1, the display panel PNL is a liquid crystal display panel. A color filter substrate of the liquid crystal display panel may be used as the cover plate CF, and a frame sealing adhesive of the liquid crystal display panel may be used as the adhesive layer EA; and a liquid crystal cell surrounded by the frame sealing adhesive is arranged between the color filter substrate and the array substrate ARR, and liquid crystal LC is filled in the liquid crystal cell. The organic film layer ORG on the array substrate ARR is provided with the blocking groove BG in the peripheral area BB; when the array substrate ARR and the color filter substrate are aligned and combined with each other through the frame sealing adhesive, the frame sealing adhesive may fill the blocking groove BG. Therefore, on one hand, a path for moisture to enter can be blocked, and on the other hand, a bonding area between the array substrate ARR and the frame sealing adhesive can be increased, so that the adhesive force between the array substrate ARR and the frame sealing adhesive is improved, and a problem that the array substrate ARR is easy to peel off from the frame sealing adhesive due to the organic film layer ORG is solved.

Certainly, the display panel PNL of the present disclosure may alternatively be another type of display panel, such as a display panel having self-luminous elements, in which the light-emitting elements and pixel driving circuits for driving the light-emitting elements may be provided on the array substrate ARR of the display panel PNL. A light-transmitting cover plate CF, such as a glass cover plate, may be attached on a light outgoing side of the array substrate ARR by a frame sealing adhesive or an optical adhesive. Illustratively, the display panel PNL may alternatively be an OLED (organic light-emitting diode) display panel, a PLED (polymer organic light-emitting diode) display panel, a Micro LED (Micro light-emitting diode) display panel, a QD-OLED (quantum dot-organic light-emitting diode) display panel, a QLED (quantum dot light-emitting diode) display panel, or other types of self-luminous display panels.

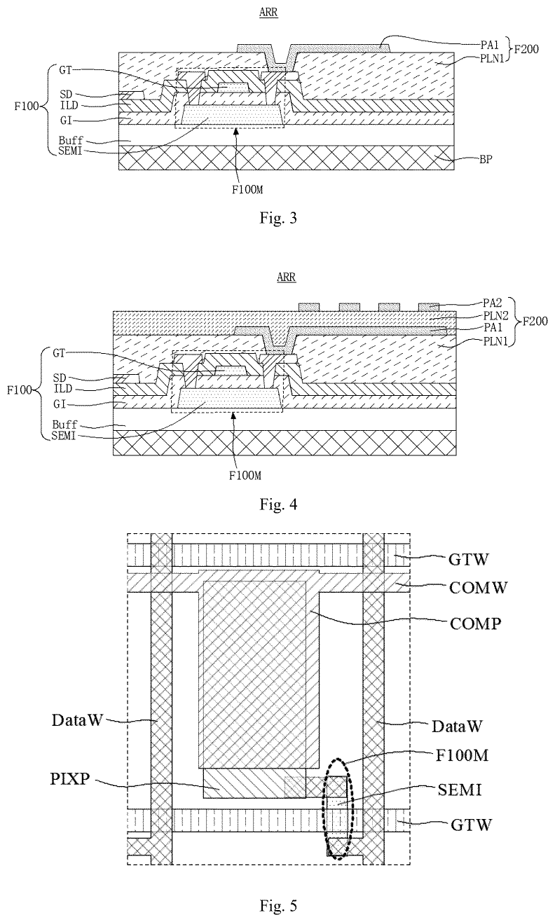

Referring to FIGS. 3 and 4, in some implementations, the array substrate ARR of the present disclosure may include a base substrate BP, a driving circuit layer F100, and an electrode composite layer F200, which are sequentially stacked.

The electrode composite layer F200 is provided with a pixel electrode, and the driving circuit layer F100 is provided with a pixel driving circuit for driving the pixel electrode. In a self-luminous display panel, the light-emitting elements of the array substrate ARR may be provided in the electrode composite layer F200, or the electrode composite layer F200 of the array substrate ARR may be a part of a layer where the light-emitting elements are located. In the embodiments of the present disclosure, the structure of the display panel PNL of the present disclosure and a method for manufacturing the display panel PNL of the present disclosure are exemplarily described only by taking the display panel PNL being a liquid crystal display panel as a specific example. It is understood that the technical means and effects achieved in the exemplary description of the structure of the display panel and the method for manufacturing the display panel according to the embodiments of the present disclosure may be applied to an array substrate of a self-luminous display panel directly or after being reasonably modified.

In the display panel PNL of the embodiment of the present disclosure, the electrode composite layer F200 of the array substrate ARR includes at least one electrode layer, at least one of which is used as a pixel electrode layer. The pixel electrode layer is provided with a pixel electrode of the display panel PNL. A common electrode layer of the display panel PNL may be provided in the array substrate ARR or provided on the cover plate CF.

In an implementation, referring to FIG. 4, the electrode composite layer F200 of the array substrate ARR may include two electrode layers (i.e., a first electrode layer PA1 and a second electrode layer PA2) which are stacked. For example, referring to FIG. 4, the electrode composite layer F200 of the array substrate ARR includes a first planarization layer PLN1 (made of an organic material), the first electrode layer PA1, an insulating dielectric layer, and the second electrode layer PA2, which are sequentially stacked on a side of the driving circuit layer F100 away from the base substrate BP. The insulating dielectric layer may be an inorganic dielectric layer, an organic dielectric layer or a composite stacking structure of the organic dielectric layer and the inorganic dielectric layer. As an example, referring to FIG. 4, the insulating dielectric layer includes a second planarization layer PLN2 (made of an organic material). The second planarization layer PLN2 may be directly provided on a surface of the first electrode layer PA1 away from the base substrate BP. Alternatively, an inorganic dielectric layer is provided between the second planarization layer PLN2 and the first electrode layer PA1.

One of the first electrode layer PA1 and the second electrode layer PA2 is a common electrode layer provided with a common electrode, and the other of the first electrode layer PA1 and the second electrode layer PA2 is a pixel electrode layer provided with a pixel electrode. Each of the common electrode and the pixel electrode may be a plate electrode or a hollow-out electrode (e.g., a slit electrode).

Exemplarily, in an implementation of the present disclosure, referring to FIG. 4, the first electrode layer PA1 serves as the pixel electrode layer provided with the pixel electrode that is the plate electrode. The second electrode layer PA2 is the common electrode layer, and the common electrode is the hollow-out electrode.

In the array substrate ARR of the embodiment of the present disclosure, at least one of the first electrode layer PA1 or the second electrode layer PA2 is a transparent electrode layer, for example, a transparent metal electrode layer (for example, a magnesium-silver alloy layer, an aluminum-silver alloy layer, or the like) or a transparent metal oxide electrode layer (for example, an indium-tin oxide layer). In an example, the first electrode layer PA1 and the second electrode layer PA2 are both transparent electrode layers, for example, materials of the first electrode layer PA1 and the second electrode layer PA2 are both indium tin oxide (ITO).

In another implementation, referring to FIG. 3, the electrode composite layer F200 of the array substrate ARR may include one electrode layer, i.e., only the first electrode layer PA1 is provided. For example, referring to FIG. 3, the electrode composite layer F200 of the array substrate ARR includes a first planarization layer PLN1 and a first electrode layer PA1 sequentially stacked on a side of the driving circuit layer F100 away from the base substrate BP. The first electrode layer PA1, as a pixel electrode layer, is provided with a pixel electrode.

In some implementations of the present disclosure, the electrode composite layer F200 further includes an alignment layer for controlling pretilt angles of liquid crystal molecules.

In some implementations of the present disclosure, the electrode composite layer F200 further includes a support pillar layer formed with a plurality of support pillars for improving stability of a thickness of the liquid crystal cell.

In the display panel PNL according to the embodiment of the present disclosure, the base substrate BP may be a base substrate made of an inorganic material or a base substrate made of an organic material. For example, in an implementation of the present disclosure, a material of the base substrate BP may be a glass material such as soda-lime glass, quartz glass, or sapphire glass, or may be a metal material such as stainless steel, aluminum, or nickel. In another implementation of the present disclosure, the material of the base substrate BP may be polymethyl methacrylate (PMMA), polyvinyl alcohol (PVA), polyvinyl phenol (PVP), polyether sulfone (PES), polyimide, polyamide, polyacetal, polycarbonate (PC), polyethylene terephthalate (PET), polyethylene naphthalate (PEN), or a combination thereof. Certainly, in other implementations of the present disclosure, for example, in a self-luminous display panel PNL, the base substrate BP may alternatively be a flexible base substrate BP, for example, a material of the base substrate BP may be polyimide (PI). The base substrate BP may alternatively be a composite of multiple layers of materials. For example, in an implementation of the present disclosure, the base substrate BP may include a bottom film layer, a pressure sensitive adhesive layer, a first polyimide layer, and a second polyimide layer, which are sequentially stacked. It is to be understood that, in a case where the liquid crystal display panel PNL exemplified in the implementation of the present disclosure is a transmissive liquid crystal display panel PNL, the base substrate BP is made of a transparent material.

The driving circuit layer F100 of the array substrate ARR of the embodiment of the present disclosure is provided with pixel driving circuits for driving pixel electrodes of sub-pixels. In the driving circuit layer, each pixel driving circuit may include a transistor. Further, referring to FIGS. 3 and 4, the transistor may be a thin film transistor, and the thin film transistor may be selected from a top gate type thin film transistor, a bottom gate type thin film transistor, or a dual gate type thin film transistor; a material of an active layer of the thin film transistor may be an amorphous silicon semiconductor material, a low-temperature polycrystalline silicon semiconductor material, a metal oxide semiconductor material, an organic semiconductor material or any other type of semiconductor material; the thin film transistor may be an N-type thin film transistor or a P-type thin film transistor. In this example, the pixel driving circuit may be a switching transistor F100M.

In some implementations, referring to FIGS. 3 and 4, the driving circuit layer may include a semiconductor layer SEMI, a gate insulation layer GI, a gate layer GT, an interlayer dielectric layer ILD, a source-drain metal layer SD, and the like, which are stacked between the base substrate BP and the electrode composite layer F200. The switching transistor may be formed of film layers such as the semiconductor layer SEMI, the gate insulation layer GI, the gate layer GT, the interlayer dielectric layer ILD and the source-drain metal layer SD. Positions of the film layers may be determined according to a structure of the thin film transistor. In an example, the driving circuit layer may include the semiconductor layer SEMI, the gate insulation layer GI, the gate layer GT, the interlayer dielectric layer ILD, and the source-drain metal layer SD sequentially stacked, and the switching transistor thus formed is a top gate type thin film transistor. In another example, the driving circuit layer may include the gate electrode layer GT, the gate insulation layer GI, the semiconductor layer SEMI, the interlayer dielectric layer ILD, and the source-drain metal layer SD sequentially stacked, and the thin film transistor thus formed is a bottom gate type thin film transistor.

In an example, a thickness of the gate layer GT may be in a range from 0.1 μm to 1 μm, such as in a range from 0.3 μm to 0.5 μm. The gate layer GT may be a single metal layer (e.g., a copper layer) or may include multiple metal layers (e.g., Ti/Al/Ti, Mo/Cu/Mo, etc.) stacked in sequence, and the metal layers may include an alloy layer, such as a MoNi alloy layer. Certainly, in some examples, the gate layer GT may alternatively include a conductive non-metal layer, for example a TiN layer.

In an example, a thickness of the source-drain metal layer SD may be in a range from 0.1 μm to 1 μm, such as in a range from 0.3 μm to 0.5 μm. The source-drain metal layer SD may be a single metal layer (e.g., a copper layer), or may include multiple metal layers (e.g., Ti/Al/Ti, Mo/Cu/Mo, etc.) stacked in sequence, and these metal layers may include an alloy layer, such as a MoNi alloy layer. Certainly, in some examples, the gate layer GT may alternatively include a conductive non-metal layer, for example a TiN layer.

In some implementations, referring to FIG. 5, the driving circuit layer may include a plurality of data voltage lines DataW, and the data voltage lines DataW may extend in a column direction as a whole, and may extend in a straight line or may be a folding line that is bent back and forth in a row direction. Further, the data voltage lines DataW may be provided in the source-drain metal layer.

Referring to FIG. 5, the gate layer GT includes a plurality of scan lines GTW. In this example, one end of the switching transistor F100M is connected to the data voltage line DataW, the other end of the switching transistor is connected to the pixel electrode PIXP, and a gate of the switching transistor is connected to the scan line GTW. Under the control of a scan voltage loaded on the scan line GTW, the switching transistor F100M may be turned on, so that a data voltage on the data voltage line DataW is loaded to the pixel electrode.

The scan lines GTW may extend in the row direction as a whole. The scan lines GTW each may be a straight line extending in the row direction, or may be a folding line bent back and forth in the column direction. The scan lines GTW and the data voltage lines DataW may define a plurality of pixel regions, and pixel electrodes and switching transistors may be provided in the pixel regions.

In some implementations, referring to FIGS. 3 and 4, an active layer of the switching transistor F100M is provided in the semiconductor layer SEMI. The active layer of the switching transistor may include a source contact region, a channel region, and a drain contact region connected in sequence, the source contact region being connected to the data voltage line DataW through a via hole, the drain contact region being connected to the pixel electrode through a via hole. In an example, the scan line GTW overlaps the channel region of the switching transistor, such that a portion of the scan line GTW overlapping the channel region of the switching transistor may serve as the gate of the switching transistor. In other examples, the switching transistor is a bottom gate type thin film transistor, and a size of the portion of the scan line GTW overlapping the channel region of the switching transistor may be locally increased, so that the scan line GTW completely blocks the channel region of the switching transistor, which can prevent light from irradiating the channel region of the switching transistor from the base substrate BP side to cause changes in characteristics (for example, increase of a leakage current) of the switching transistor.

In some implementations, referring to FIG. 5, the electrode composite layer F200 of the array substrate ARR further includes a common electrode layer provided with a common electrode COMP and a common electrode line COMW connecting common electrodes COMP adjacent thereto. Certainly, in other implementations of the present disclosure, the common electrode line COMW may alternatively be provided in another film layer, such as the gate layer GT.

In some examples, the driving circuit layer may further include a passivation layer provided on a side of the source-drain metal layer SD away from the base substrate BP for protecting the source-drain metal layer SD.

In some examples, the driving circuit layer may further include an inorganic buffer layer Buff provided on a surface of the base substrate BP, and the gate layer GT, the semiconductor layer SEMI, the source-drain metal layer SD are provided on a side of the inorganic buffer layer Buff away from the base substrate BP.

In the exemplary array substrate ARR, materials of the inorganic buffer layer Buff, the passivation layer, the interlayer dielectric layer ILD, and the gate insulation layer GI may be dielectric materials such as silicon oxide, silicon nitride, and silicon oxynitride. For example, the passivation layer and the interlayer dielectric layer ILD are made of silicon nitride, and the inorganic buffer layer Buff and the gate insulation layer GI are made of silicon oxide.

In some implementations of the present disclosure, the array substrate may include a base substrate BP, an electrode composite layer F200, and a driving circuit layer F100, which are sequentially stacked, or the driving circuit layer F100 and the electrode composite layer F200 are mixed with each other, or the driving circuit layer F100 is sandwiched between the electrode composite layers F200 and the base substrate BP. For example, the array substrate ARR includes the base substrate BP, a first electrode layer PA1, a gate layer GT, a gate insulation layer GI, a semiconductor layer SEMI, a source-drain metal layer SD, a planarization layer PLN, and a second electrode layer PA2, which are sequentially stacked. The first electrode layer PA1 and the gate layer GT are located in a same film layer and are made of different materials, and are two layers which are mutually nested; the first electrode layer PA1 and the second electrode layer PA2 serve as two electrode layers of the electrode composite layer F200, and the semiconductor layer SEMI, the source-drain metal layer SD, the gate layer GT and the like serve as film layers of the driving circuit layer F100. In the present disclosure, these possible stacking arrangements of the film layers in the array substrate ARR each are applicable to a method for manufacturing the array substrate ARR of the present disclosure.

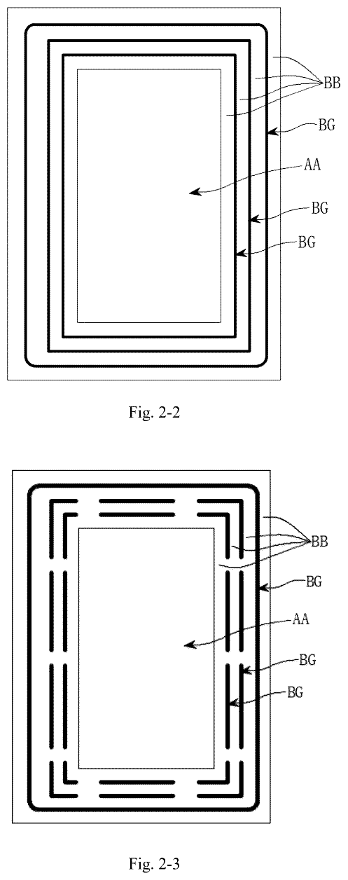

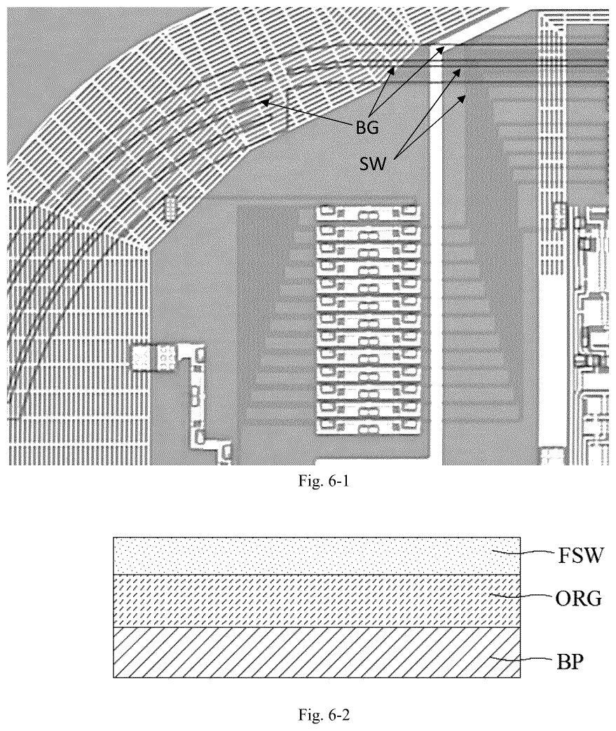

Referring to FIG. 6-2, in the array substrate ARR of the embodiment of the present disclosure, the electrode composite layer F200 has a sub-structure including an organic film layer ORG and a conductive layer FSW located on a side of the organic film layer ORG away from the base substrate BP. For example, the electrode composite layer F200 of the array substrate ARR includes the first planarization layer PLN1 and the first electrode layer PA1 stacked in sequence, the first planarization layer PLN1 and the first electrode layer PA1 may constitute a sub-structure. In this sub-structure, the first planarization layer PLN1 serves as the organic film layer ORG, and the first electrode layer PA1 serves as the conductive layer FSW. For another example, the display panel PNL includes a first planarization layer PLN1, a first electrode layer PA1, a second planarization layer PLN2, and a second electrode layer PA2, which are sequentially stacked, the second planarization layer PLN2 and the second electrode layer PA2 may form a sub-structure. In this sub-structure, the second planarization layer PLN2 serves as the organic film layer ORG, and the second electrode layer PA2 serves as the conductive layer FSW. Certainly, in this example, the first planarization layer PLN1 and the first electrode layer PA1 may also constitute a sub-structure. For another example, the electrode composite layer F200 is provided with a planarization layer PLN and a second electrode layer PA2 on a side of the source-drain metal layer SD away from the base substrate BP, so that the planarization layer PLN may serve as the organic film layer ORG, and the second electrode layer PA2 may serve as the conductive layer FSW.

In some implementations of the present disclosure, a thickness of the organic film layer ORG may be in a range from 0.5 μm to 5 μm, for example, in a range from 1.5 μm to 3 μm.

In some implementations of the present disclosure, a width of the blocking groove BG formed on the organic film layer ORG may be in a range from 10 μm to 200 μm.

In some implementations of the present disclosure, the blocking groove BG is provided in the peripheral area BB of the array substrate ARR and surrounds the display area AA, for example, the blocking groove BG is provided in an adhesive coating area, for coating the frame sealing adhesive, of the display panel PNL.

In an example, referring to FIGS. 2-2 and 2-3, a plurality of blocking grooves BG are provided, and at least part of the blocking grooves BG are sequentially arranged around the display area AA. Further, the number of the blocking grooves BG at different positions may be the same or different. For example, referring to FIG. 6-1, at a corner of the array substrate ARR, there are four blocking grooves BG, and at a non-corner position, there are two blocking grooves BG. In this way, a strength of frame sealing at the corner can be improved, avoiding defects such as punctures occurring in the display device at the corner.

In an example, referring to FIG. 2-3, at least part of the blocking grooves BG may be discontinuous, i.e., the blocking groove BG may include a plurality of blocking sub-grooves.

In another example, referring to FIGS. 2-1 and 2-3, at least one of the blocking grooves BG is continuous, i.e., this blocking groove is in a continuous ring shape.

Certainly, in other implementations of the present disclosure, as shown in FIG. 2-1, the array substrate ARR may have only one blocking groove.

In an example, in at least a partial region, a trech is provided between two adjacent blocking grooves BG, so that the two adjacent blocking grooves BG are communicated with each other.

In an example, the blocking groove BG penetrates through the organic film layer ORG in a normal direction of the array substrate ARR.

In some implementations of the present disclosure, referring to FIG. 6-1, the conductive layer FSW may include a signal line SW crossing an edge of the blocking groove BG, for example, at least one signal line SW crosses two opposite sidewalls of the blocking groove BG (i.e., sidewalls of the organic film layer ORG), or at least one signal line SW crosses one of the sidewalls of the blocking groove BG and then continues to be extended or terminated in the blocking groove BG.

As an example, the signal line SW may be a clock line for transmitting a clock signal. Certainly, the signal line SW may alternatively transmit any other signal.

In an example, at least part of the signal lines SW each have a width in a range from 10 μm to 20 μm, and a gap between at least part of the signal lines SW is in a range from 10 μm to 20 μm. Certainly, in other examples of the present disclosure, the width of each signal line SW and the gap between the signal lines SW may be set as desired. For example, the width of each of at least part of the signal lines SW may be reduced to be in a range from 3 μm to 10 μm, or the gap between at least part of the signal lines SW may be reduced to be in a range from 3 μm to 10 μm.

It can be understood that due to the manufacturing process error, different patterns formed by a same exposure process with photoresist of different thicknesses in the photolithography process, and the like, the widths of the same signal line SW at different positions may be different. For example, the width of the signal line SW on the sidewall of the organic film layer ORG may be smaller than the width of the signal line SW on a bottom of the blocking groove BG.

In some implementations, the driving circuit layer includes a ground line in the peripheral area BB. In an area where the ground line is overlapped with the frame sealing adhesive, the ground line is in a mesh shape to improve the light transmittance of the ground line, which is beneficial to curing the frame sealing adhesive. Furthermore, in an area where the ground line is not overlapped with the frame sealing adhesive, the ground line is not designed as a hollowed-out structure, that is, the ground line is of a whole-surface structure, so as to reduce an impedance of the ground line.

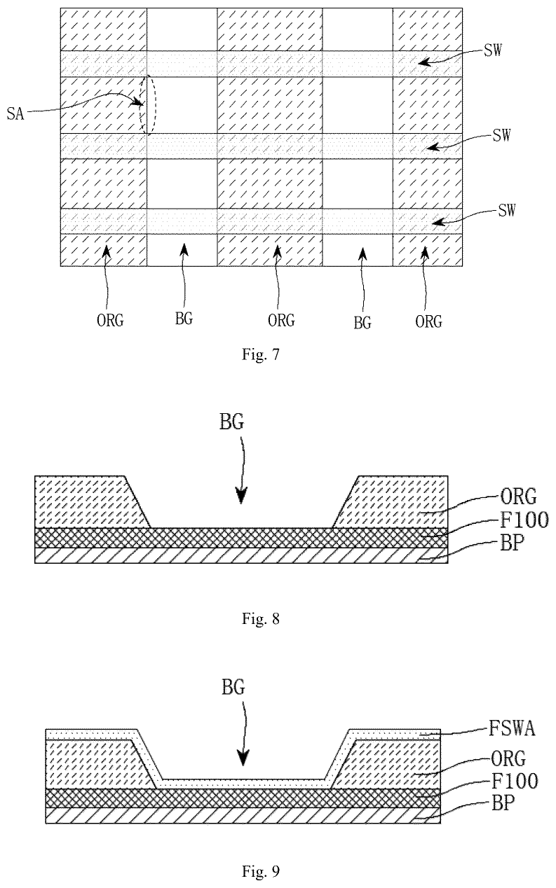

Referring to FIG. 7, in the related art, in a case where the signal line SW passes through the edge of the blocking groove BG, a short-circuit failure is likely to occur between two adjacent signal lines SW. By analyzing such a failure, it is found that a conductive material is left between the two adjacent signal singl lines SW in an edge area SA of the blocking groove BG. The manufacturing process of the array substrate ARR in the related art is traced. Referring to FIGS. 8 to 12, the array substrate ARR in the related art is manufactured by the following steps S011 to S015.

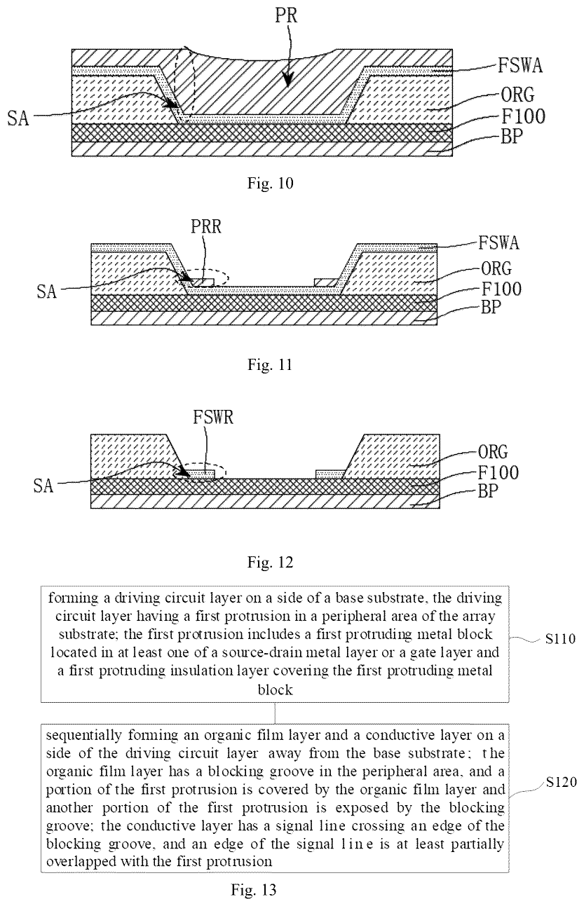

At step S011, referring to FIG. 8, a base substrate BP, a driving circuit layer F100, and an organic film layer ORG provided with the blocking groove BG are sequentially prepared. At step S012, referring to FIG. 9, a conductive material layer FSWA is formed on a surface of the organic film layer ORG away from the base substrate BP. Then, referring to FIGS. 10 to 12, the conductive material layer FSWA is patterned by a photolithography process. Specifically, at step S013, referring to FIG. 10, a photoresist PR is filled on a side of the conductive material layer FSWA away from the base substrate BP. The photoresist PR fills the blocking groove BG; due to the fluidity of the photoresist, the photoresist PR has a largest thickness at an edge area SA of the blocking groove BG. At step S014, referring to FIG. 11, the photoresist PR is exposed and developed. In the edge area SA of the blocking groove BG, the photoresist PR may not be sufficiently exposed and thus is remained, and the remained photoresist PRR may shield and protect the conductive material layer FSWA therebelow (on a side close to the base substrate BP). At step S015, referring to FIG. 12, when the conductive material layer FSWA is patterned by etching, a portion of the conductive material shielded by the remained photoresist PRR may not be sufficiently etched and thus is remained, and the remained conductive material FSWR may cause a short-circuit between two adjacent signal lines SW. In the present disclosure, the remained photoresist PRR refers to a portion of the photoresist that is expected to be exposed and developed to be removed is remained due to insufficient exposure and development. Portions that are not intended to be developed so as to be reserved (i.e., as a mask for subsequent etching) according to the process are normally reserved photoresist and not the remained photoresist PRR.

The inventor tries to eliminate the photoresist residue (remained photoresist) by overexposure to alleviate the short-circuit failure, but it is found that the exposure time may be greatly prolonged, the exposure beat is influenced, the influence on the productivity is large, and the cost of the array substrate ARR is increased. In addition, the inventor also finds that the overexposure solution is more and more restricted by the process capability of the exposure machine as the width of the signal line SW and the gap between the signal lines SW become smaller and smaller.

In order to eliminate such a short-circuit failure, referring to FIG. 13, in a first solution provided in the embodiment of the present disclosure, the array substrate ARR of the embodiment of the present disclosure may be manufactured by a method shown in the following steps S110 to S120.

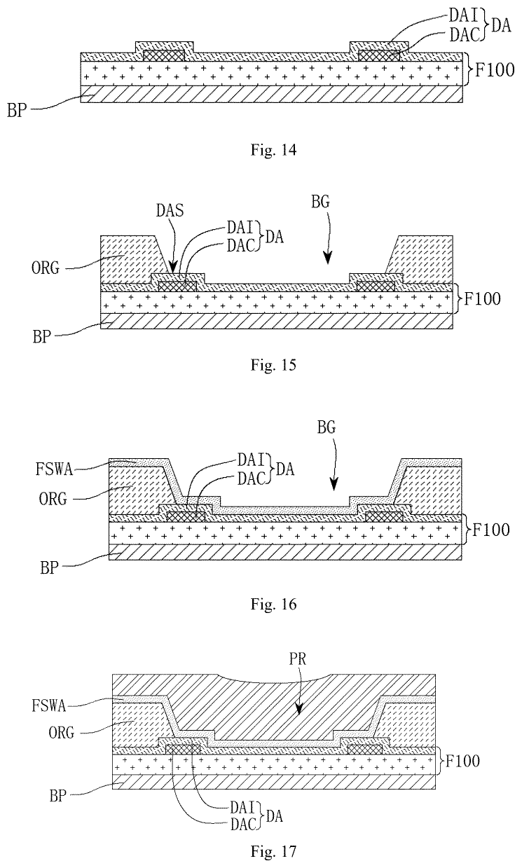

At step S110, referring to FIG. 14, a driving circuit layer F100 is formed on a side of a base substrate BP, the driving circuit layer F100 having a first protrusion DA in a peripheral area BB of the array substrate ARR; the first protrusion DA includes a first protruding metal block DAC and a first protruding insulation layer DAI covering the first protruding metal block DAC, the first protruding metal block DAC being located in at least one of a source-drain metal layer SD or a gate layer GT.

At step S120, referring to FIGS. 15 to 29, an organic film layer ORG and a conductive layer FSW are sequentially formed on a side of the driving circuit layer F100 away from the base substrate BP. The organic film layer ORG has a blocking groove BG in the peripheral area BB, and one portion of the first protrusion DA is covered by the organic film layer ORG and the other portion of the first protrusion DA is exposed by the blocking groove BG. Therefore, the exposed portion of the first protrusion DA forms a protruding step DAS protruding from a bottom of the blocking groove BG. The conductive layer FSW has a signal line SW crossing an edge of the blocking groove BG, and an edge of the signal line SW is at least partially overlapped with the first protrusion DA. In other words, the edge of the signal line SW is at least partially supported by the protruding step DAS.

In an example, the organic film layer ORG and the conductive layer FSW are prepared as a part of the electrode composite layer F200. In other words, at step S120, the electrode composite layer F200 is prepared on a side of the driving circuit layer F100 away from the base substrate BP. The electrode composite layer F200 includes the organic film layer ORG and the conductive layer FSW on the side of the organic film layer ORG away from the base substrate BP.

In an example, the step S120 may include steps S121 to S126.

At step S121, referring to FIG. 15, the organic film layer ORG is formed on the side of the driving circuit layer F100 away from the base substrate BP, and the organic film layer ORG has the blocking groove BG in the peripheral area BB. A portion of the first protrusion DA is covered by the organic film layer ORG, and another portion of the first protrusion DA is exposed in the blocking groove BG. In other words, the first protrusion DA is located at a lower edge (an edge close to the base substrate) of the blocking groove BG. The portion of the first protrusion DA exposed to the blocking groove BG forms the protruding step DAS.

At step S122, referring to FIG. 16, a conductive material layer FSWA is formed on a side of the organic film layer ORG away from the base substrate BP, the conductive material layer FSWA covering the organic film layer ORG and the blocking groove BG. The conductive material layer FSWA covers the protruding step DAS in the blocking groove BG.

At step S123, referring to FIG. 17, a photoresist PR is coated on a side of the conductive material layer FSWA away from the base substrate BP, the photoresist PR filling the blocking groove BG. Referring to FIG. 17, a thickness of a portion of the photoresist PR above the protruding step DAS is reduced due to lifting of the first protrusion DA.

At step S124, the photoresist PR is exposed and developed. In the edge area of the blocking groove BG, the portion of the photoresist PR lifted by the protruding step DAS is reduced in thickness and can be sufficiently exposed and is not easy to be remained.

At step S125, the conductive material layer FSWA is etched to form a desired structure, for example, a desired signal line SW. In this process, at a portion of the blocking groove BG lifted by the protruding step DAS in the edge area of the blocking groove BG, the conductive material can be fully etched due to no shielding of remained photoresist, so that an accurate pattern of the signal line SW can be ensured to be formed, and the short-circuit between the signal lines SW caused by the remained conductive material between the signal lines SW is avoided.

At step S126, the photoresist PR is removed.

In the first solution provided by the embodiment of the present disclosure, the first protrusion DA may be prepared on the driving circuit layer F100 by adjusting a mask plate for the source-drain metal layer SD or the gate layer GT without adding any process. The first protruding insulation layer DAI is an inorganic material layer located on a side of the first protruding metal block DAC away from the base substrate BP, and may be varied depending on the first protruding metal block DAC. For example, in an example, the first protruding metal block DAC is located in the source-drain metal layer SD and the first protruding insulation layer DAI is located in a passivation layer. For another example, the first protruding metal block DAC is located in the gate layer GT, and the first protruding insulation layer DAI is located in at least one of an interlayer dielectric layer ILD or a passivation layer. In another example, the first protruding metal block DAC includes a bottom metal block located in the gate layer GT and a top metal block located in the source-drain metal layer SD, the top metal block being carried on the bottom metal block, for example, the edges of the top metal block and the bottom metal block are flush; in this way, the first protruding metal block DAC may have a larger thickness, and further, a step difference (a height difference) between the protruding step DAS and the bottom of the blocking groove BG is larger.

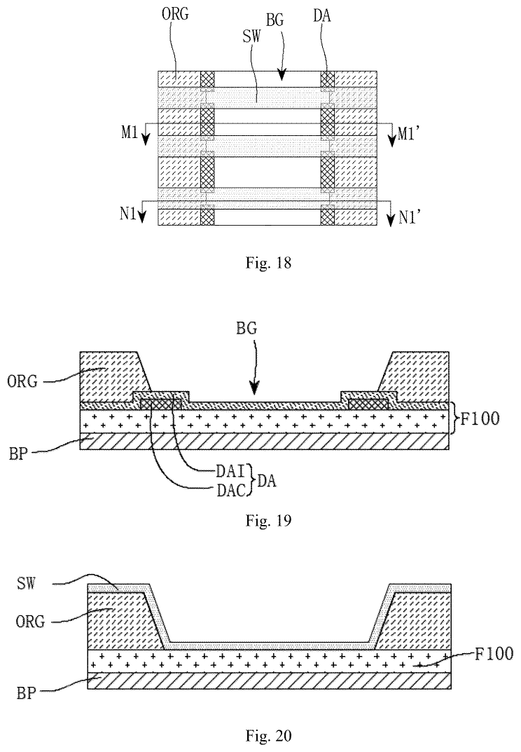

During patterning the organic material layer to form the organic film layer ORG and the blocking groove BG, the organic film layer ORG is formed to cover a portion of the first protrusion DA and the blocking groove BG exposes a portion of the first protrusion DA. Thus, referring to FIG. 15, the first protrusion DA forms the protruding step DAS connected with the sidewall of the blocking groove BG and protruding from the bottom of the blocking groove BG. Referring to FIG. 16, during froming the conductive material layer FSWA, the conductive material layer FSWA covers the protruding step DAS, so that a step difference between the conductive material layer FSWA on the protruding step DAS and a surface of the organic film layer ORG is smaller. Referring to FIG. 17, after the photoresist PR is coated, the thickness of the photoresist on the protruding step DAS is reduced and photoresist is not easily remained during exposure and development as compared to the related art. Therefore, no conductive material is remained in a portion of the gap between two adjacent signal lines SW on the protruding step DAS, and the short-circuit failure between the signal lines SW is eliminated. Thus, referring to FIGS. 18, 21, 24 and 27, in the array substrate ARR formed, the gap between the signal lines SW overlaps the first protrusion DA.

In an implementation, during patterning the conductive material layer FSWA by a photolithography process, a focal plane of the exposure machine is an upper surface of the photoresist (a surface of the photoresist away from the base substrate BP), or at a position close to the upper surface of the photoresist (e.g., a position with a distance from the upper surface of the photoresist not more than 10% of a maximum thickness of the photoresist).

In an implementation, a height of the protruding step DAS is not less than 10% of a depth of the blocking groove BG, for example, the height of the protruding step DAS is in a range from 10% to 40% of the depth of the blocking groove BG. For example, the height of the protruding step DAS is in a range from 0.3 μm to 0.5 μm, and the depth of the blocking groove BG is in a range from 1.5 μm to 3 μm. In the embodiment of the present disclosure, the depth of the blocking groove BG is a step difference between the bottom surface of the blocking groove BG (a surfact of the bottom of the blocking groove close to the base substrate BP) and a top opening of the blocking groove BG (an opening of the blocking groove away from the base substrate BP). In the embodiment of the present disclosure, the height of the protruding step DAS is a step difference between a top surface of the protruding step DAS (a surface of the protruding step DAS away from the base substrate BP) and the bottom surface of the blocking groove BG. In the embodiment of the present disclosure, the step difference refers to a distance difference between two distances, which are between two structures or planes and the base substrate BP, respectively. In an example, the height of the protruding step DAS is substantially equal to a thickness of the first protruding metal block DAC.

In an implementation, referring to FIGS. 19, 22, 24 and 27, a portion of the first protrusion DA, an orthographic projection of which on the base substrate BP is overlapped with an orthographic projection of the organic film layer ORG on the base substrate BP, has a size, not less than 2 μm, especially not less than 3 μm, for example in a range from 3 μm to 5 μm, in a direction perpendicular to the lower edge of the blocking groove BG. In this way, it can guarantee that at least a part of the first protrusion DA is covered by the organic film layer ORG, the top surface of the first protrusion DA is connected with the lateral side of blocking groove BG, and the influence of factors such as process fluctuation and alignment deviation can be overcome.

In an implementation, referring to FIGS. 18 to 20, in at least a partial region of the blocking groove BG, each of two edges of the blocking groove BG is provided with a plurality of first protrudings DA; two edges of a same signal line SW are respectively overlapped with two adjacent first protrusions DA, and the signal line SW covers a gap between the two adjacent first protrusions DA. In this way, in at least a partial region, at the same lower edge of the blocking groove BG, two edges of at least one signal line SW are respectively overlapped with two adjacent first protrusions DA. In other words, a gap is formed between at least two first protrusions DA, and at least one signal line SW covers the gap. Therefore, during curing the frame sealing adhesive, the frame sealing adhesive can be irradiated by external light through the gap, so that the curing speed of the frame sealing adhesive is improved, the production beat is improved, and the production cost is reduced.

In an example, referring to FIGS. 18 to 20, a plurality of first protrusion DA are respectively provided at two lower edges of the blocking groove BG. A gap is formed between every two adjacent first protrusions DA at any one of the lower edges of the blocking groove BG; two edges of the signal line SW are respectively overlapped with the two adjacent first protrusions DA, and the signal line SW covers the gap between the two adjacent first protrusions DA.

Further, referring to FIGS. 18 to 20, the first protrusions DA overlapping the same signal line SW and respectively located at two opposite lower edges of the blocking groove BG are not connected, that is, a gap is provided therebetween. In other words, the first protrusions DA are only arranged at positions close to the lower edges of the blocking groove BG, and the first protrusions DA are respectively and independently arranged at the two lower edges of the blocking groove BG. In such a way, a gap that is not provided with the first protrusion DA is formed between the two lower edges of blocking groove BG, which is favorable to improving the intensity of light irradiating to the frame sealing adhesive, so as to improve the curing speed of the frame sealing adhesive.

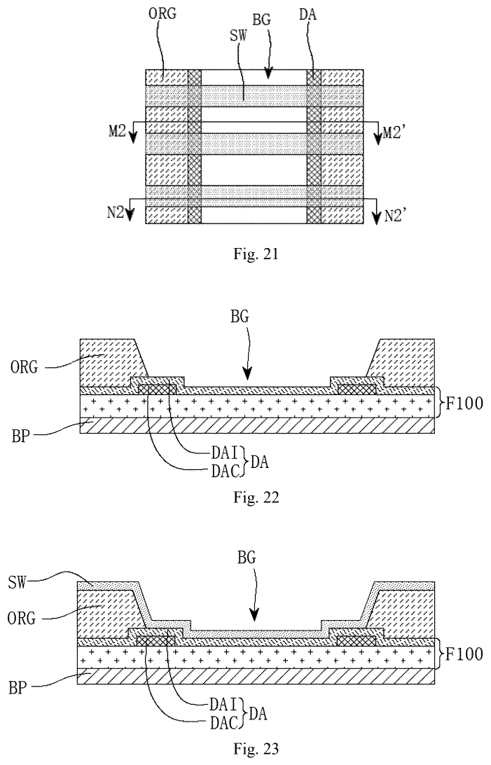

In another implementation, referring to FIGS. 21 to 23, in at least a partial region of the blocking groove BG, two edges of the blocking groove BG each are provided with one first protrusion DA, the signal line SW intersecting the first protrusion DA.

In other words, in at least a partial region, at least part of adjacent smaller first protrusions DA located at the same lower edge of the blocking groove BG may be sequentially connected to form a strip-shaped first protrusion DA. Thus, at least one signal line SW intersects the strip-shaped first protrusion DA, and two edges of the signal line SW are both overlapped with the same strip-shaped first protrusion DA. With such an arrangement, it is possible to directly provide the strip-shaped first protrusion DA without arranging the first protrusions DA each having a smaller size. On one hand, the design of the display panel PNL can be simplified, and the requirements on a size of a mask plate can be decreased; on the other hand, the limitation of process factors such as the exposure precision, the alignment deviation on the size of the first protrusion DA is eliminated, and the application range can be extended to the display panels PNL with different sizes. Moreover, the strip-shaped first protrusion DA is provided so that it can ensure that the edges of the signal line SW can overlap with the first protrusion DA, therefore, a phenomenon that the edges of the signal line SW is located in the gap between the first protrusions DA due to factors such as process fluctuations or alignment deviations can be avoided, thereby improving the process precision and overcoming potential defects.

In an example, referring to FIGS. 21 to 23, in a same group of signal lines SW sequentially adjacent to each other, the first protrusions DA overlapping the group of signal lines SW and located at the same lower edge of the blocking groove BG are connected to each other to form a strip-shaped first protrusion DA; in other words, the same group of signal lines SW sequentially adjacent to each other all intersect with the same strip-shaped first protrusion DA.

Further, referring to FIG. 21, a gap is formed between two strip-shaped first protrusions DA which are arranged oppositely, so that the gap between the first protrusions DA can transmit light, which is beneficial to improving the curing speed of the frame sealing adhesive.

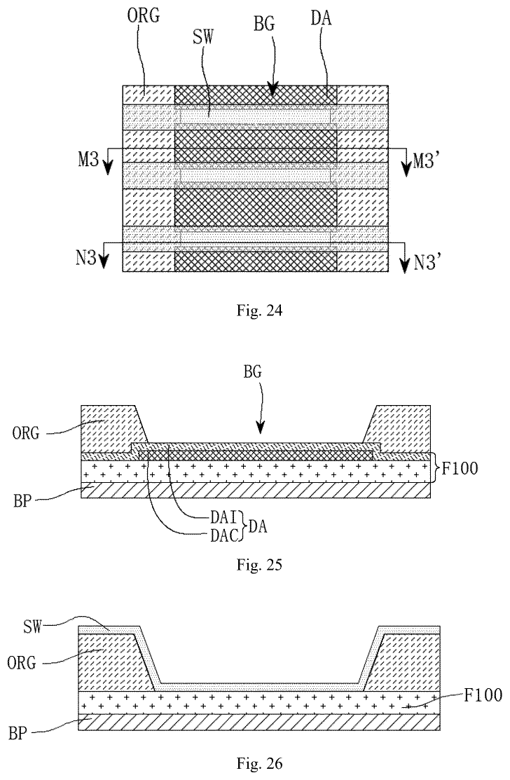

In another implementation, referring to FIGS. 24 to 26, in at least a partial region of the blocking groove BG, multiple first protrusions DA are provided; two ends of any first protrusion DA are respectively covered by the organic film layer ORG at two sides of the blocking groove BG; two edges of each of at least part of the signal lines SW are respectively overlapped with two adjacent first protrusions DA, and the signal line SW covers a gap between the two adjacent first protrusions DA. In other words, the first protrusion DA may extend along an extending direction in which the signal line SW overlapped with the first protrusion DA extends and may run through the blocking groove BG, and two ends of the first protrusion DA overlap with two sidewalls of the blocking groove BG (i.e., sidewalls of the organic film layer ORG), respectively. Therefore, the electrode material can be prevented from being left at the lower edge of the blocking groove BG, the electrode material can also be prevented from being left at the bottom of the blocking groove BG, and the risk of short-circuit of the signal line SW is further reduced.

In an example, at the bottom of the blocking groove BG, an edge of any one of the signal lines SW is located on the first protrusion DA (on a side of the first protrusion DA away from the base substrate BP), and two edges of the signal line SW are respectively located on two different first protrusions DA. A gap is formed between every two adjacent first protrusions DA, the signal line SW covers the gap, and two edges of the signal line SW are respectively overlapped with the two first protrusions DA. Especially, in the blocking groove BG with a small width (a dimension perpendicular to an extension direction in which the blocking groove BG extends), for example, in a case where the width of the blocking groove BG is in a range from 10 μm to 30 μm, with such an arrangement of the first protrusion DA, the design of the first protrusion DA can be simplified and the requirements on the process can be reduced.

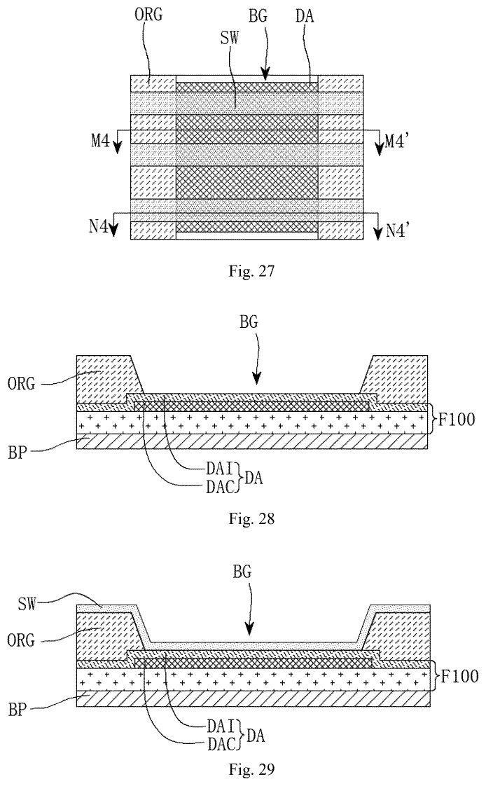

In another implementation, referring to FIGS. 27 to 29, in at least a partial region of the blocking groove BG, one first protrusion DA is provided, and both sides of the first protrusion DA are covered by the organic film layer ORG on both sides of the blocking groove BG, respectively; a portion of at least part of signal lines SW at the bottom surface of the blocking groove BG is carried on the first protrusion DA.

In other words, at least one first protrusion DA is overlapped with a plurality of adjacent signal lines SW, and the portions of the signal lines SW at the bottom of the blocking groove BG are completely located on the first protrusion DA. In other words, in at least a partial region of the blocking groove BG, orthographic projections of the portions of the plurality of signal lines SW at the groove bottom of the blocking groove BG on the base substrate BP are located within an orthographic projection of a same first protrusion DA on the base substrate BP.

In an implementation of the present disclosure, the driving circuit layer F100 is provided with a ground line in the peripheral area BB, where the ground line at least partially overlaps with the blocking groove BG; at least part of the first protruding metal blocks DAC is a part of the ground line. In this way, the short-circuit failure in the blocking groove BG can be reduced by locally adjusting a pattern of the ground line, and the purpose of improving the yield can be achieved without increasing the manufacturing cost of the array substrate ARR.

In another implementation of the present disclosure, the driving circuit layer F100 is provided with a ground line in the peripheral area BB, where the ground line is at least partially overlapped with the blocking groove BG; a position where the signal line SW crosses the edge of the blocking groove BG is not overlapped with the ground line.

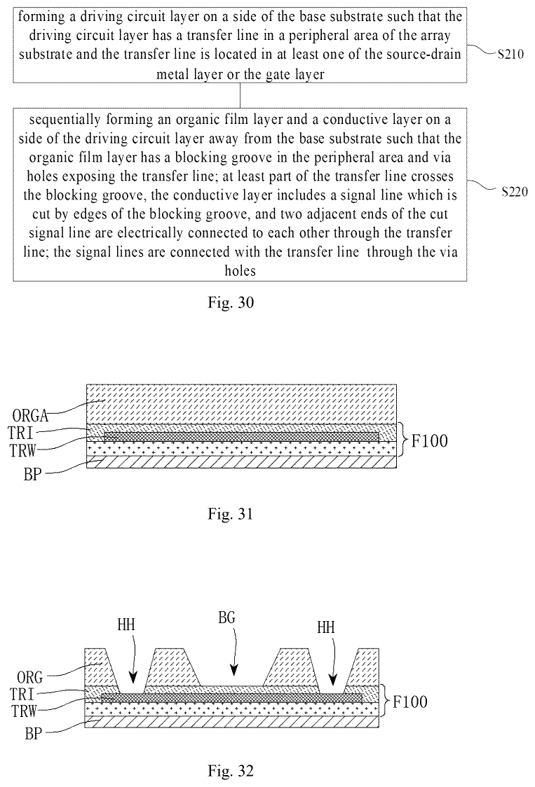

Referring to FIG. 30, in a second solution provided by the present disclosure, the array substrate ARR of the present disclosure may be manufactured by the following method shown in steps S210 to S220.

At step S210, referring to FIG. 31, a driving circuit layer F100 is formed on a side of the base substrate BP, and the driving circuit layer F100 has a transfer line TRW in a peripheral area BB of the array substrate ARR, where the transfer line TRW is located in at least one of the source-drain metal layer SD or the gate layer GT.

At step S220, referring to FIGS. 31 to 36, an organic film layer ORG and a conductive layer FSW are sequentially formed on a side of the driving circuit layer F100 away from the base substrate BP; the organic film layer ORG has a blocking groove BG in the peripheral area BB and via holes HH exposing the transfer line TRW; at least part of the transfer line TRW crosses the blocking groove BG (that is, two ends of the transfer line TRW are respectively located at two sides of the blocking groove BG); the conductive layer FSW includes a signal line SW which is cut by edges of the blocking groove BG, and two adjacent ends of the cut signal line SW are electrically connected through the transfer line TRW; the signal line SW is connected with the transfer line TRW through the via hole HH. In this way, the signal line SW crosses the blocking groove BG through the transfer line TRW in the driving circuit layer F100, and even if a conductive material is remained in the blocking groove BG, the remained conductive material can not be electrically connected to the signal line SW. Therefore, the short-circuit between the signal lines SW caused by the remained conductive material in the blocking grooves BG can be avoided.

In an example, the organic film layer ORG and the conductive layer FSW are prepared as a part of the electrode composite layer F200. In other words, in step S220, the electrode composite layer F200 is prepared on the side of the driving circuit layer F100 away from the base substrate BP. The electrode composite layer F200 includes the organic film layer ORG and the conductive layer FSW located on a side of the organic film layer ORG away from the base substrate BP.

In an example, the conductive layer FSW further includes a conductive material in the blocking groove BG at an edge of the blocking groove BG, and the conductive material is disconnected from the signal line SW.

In an example, referring to FIG. 31, the driving circuit layer F100 further includes a transfer insulation layer TRI covering the transfer line TRW in the peripheral area BB. Referring to FIG. 32, during forming the via holes HH for electrically connecting the signal line SW with the transfer line TRW, the via holes HH penetrate through the organic film layer ORG and the transfer insulation layer TRI, so that two ends of the transfer line TRW are exposed through two via holes HH located at two sides of the blocking groove BG, respectively. The transfer insulation layer TRI may be adjusted correspondingly according to the transfer line TRW. For example, in a case where the transfer line TRW is located in the source-drain metal layer SD, the transfer insulation layer TRI may be located in a passivation layer. As another example, in a case where the transfer line TRW is located in the gate layer GT, the transfer insulation layer TRI may be located in one or both of an interlayer dielectric layer ILD or the passivation layer.

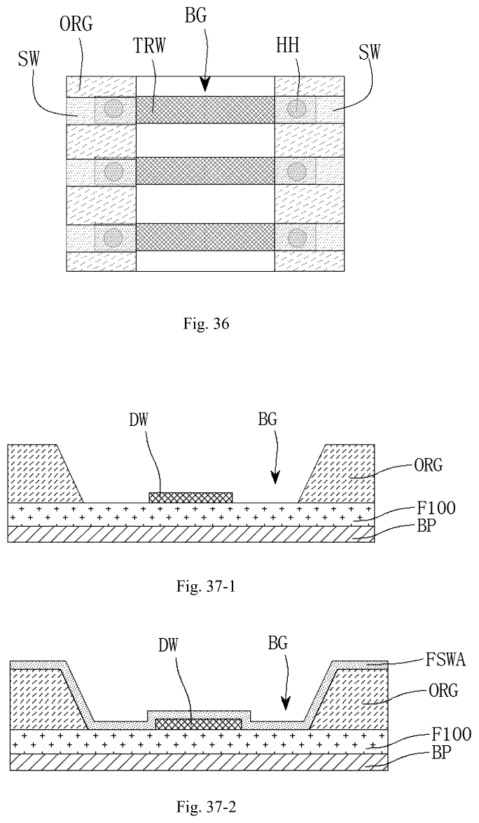

In an example, referring to FIG. 36, at least part of the transfer line TRW crosses the blocking groove BG, and two ends of the transfer line TRW are respectively exposed by the via holes HH; at least part of the signal line SW is cut off by the blocking groove BG, and two adjacent ends of the cut signal line SW are connected with two ends of the transfer line TRW through the via holes HH, respectively.

In an example, referring to FIG. 36, in at least a partial region of the array substrate ARR, the number of the transfer lines TRW crossing the blocking groove BG is the same as the number of the signal lines SW required to cross the blocking grooves BG, and the transfer lines TRW and the signal lines SW are arranged in a one-to-one correspondence. Two adjacent ends of the signal line SW cut off by the blocking groove BG are electrically connected with two ends of the transfer line TRW corresponding thereto through the via holes HH, respectively. In a further example, each signal line SW crosses the blocking groove BG through the transfer line TRW.

In an example, referring to FIG. 35, ends of the signal line SW are outside the blocking groove BG, that is, an orthographic projection of the signal line SW on the base substrate BP and an orthographic projection of the blocking groove BG on the base substrate BP are not overlapped.

In an example, at least one transfer line TRW crosses a plurality of blocking grooves BG adjacently provided; and therefore, the signal line SW can continuously cross the plurality of the blocking grooves BG through a same transfer line TRW. That is, it unnecessary to provide a plurality of different transfer lines TRW for the signal line SW to cross a plurality of different blocking grooves BG, and a via hole HH is prevented from being fromed in the organic film layer ORG between different blocking grooves BG.

In an example, at least one of the transfer lines TRW includes different line segments, with adjacent line segments being provided in the source-drain metal layer SD and the gate layer GT, respectively. In other words, the transfer line TRW can be mutually transferred (connected) between the source-drain metal layer SD and the gate layer GT to avoid other structures in the source-drain metal layer SD or the gate layer GT.

In an example, at least one signal line SW is locally positioned in the blocking groove BG and an extending direction in which the signal line SW extend is parallel to the extending direction in which the blocking groove BG extends; a portion of the signal line SW on the organic film layer ORG and a portion of the signal line SW in the blocking groove BG may also be transferred (connected) through the transfer line TRW. One end of the transfer line TRW for transferring the signal line SW is located at the organic film layer ORG and connected to the portion of the signal line SW on the organic film layer ORG through the via hole HH, and the other end of the transfer line TRW is located at the blocking groove BG and connected to the portion of the signal line SW at the blocking groove BG through the via hole HH. Thus, the transfer line TRW does not need to cross the blocking groove BG.

In an example, the step S220 may include the following steps S221 to S225.

At step S221, referring to FIG. 31, an organic material layer ORGA is formed on a side of the driving circuit layer F100 away from the base substrate BP.

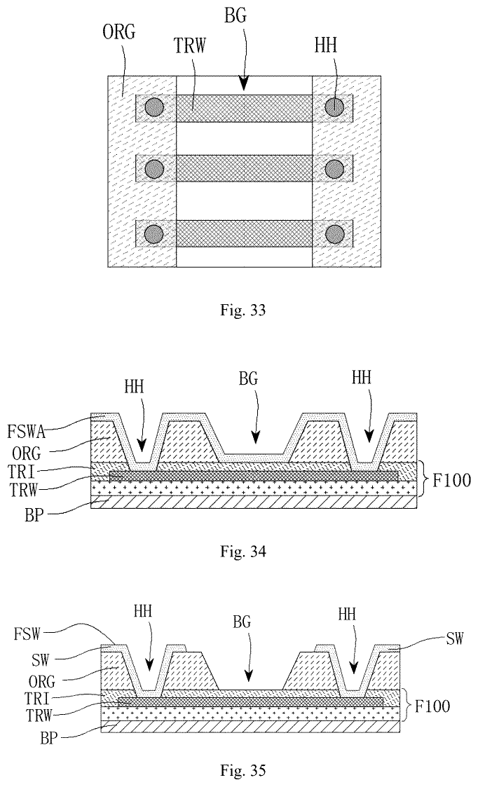

At step S222, referring to FIG. 32, the organic material layer ORGA and the transfer insulation layer TRI are patterned. The organic film layer ORG has a blocking groove BG, and the organic film layer ORG and the transfer insulation layer TRI are formed with via holes HH exposing the transfer line TRW. Referring to FIGS. 32 and 33, at least part of the transfer line TRW crosses the blocking groove BG, and two ends of the transfer line TRW are exposed by the via holes HH.

At step S223, referring to FIG. 34, a conductive material layer FSWA is formed on a side of the organic film layer ORG away from the base substrate BP, and the conductive material layer FSWA may cover the organic film layer ORG and the blocking groove BG.

At step S224, referring to FIGS. 35 and 36, the conductive material layer FSWA is patterned to prepare the signal lines SW. At least part of the signal line SW crosses the blocking groove BG through transferring by the transfer line TRW.

Referring to FIG. 37-1, in the array substrate ARR according to the embodiment of the present disclosure, a conductive structure DW located in the source-drain metal layer SD may be provided in at least part of the blocking grooves BG. In the related art, a short-circuit failure also often occurs in the source-drain metal layer SD in the isolation groove BG. By analyzing this failure, it is found that a conductive material is remained between the conductive structures DW, and the conductive structures DW are short-circuited through the remained conductive material. The preparation process of the array substrate ARR in the related art is traced. Referring to FIGS. 37-1 to 40, the array substrate ARR in the related art is prepared by the following steps S021 to S025.

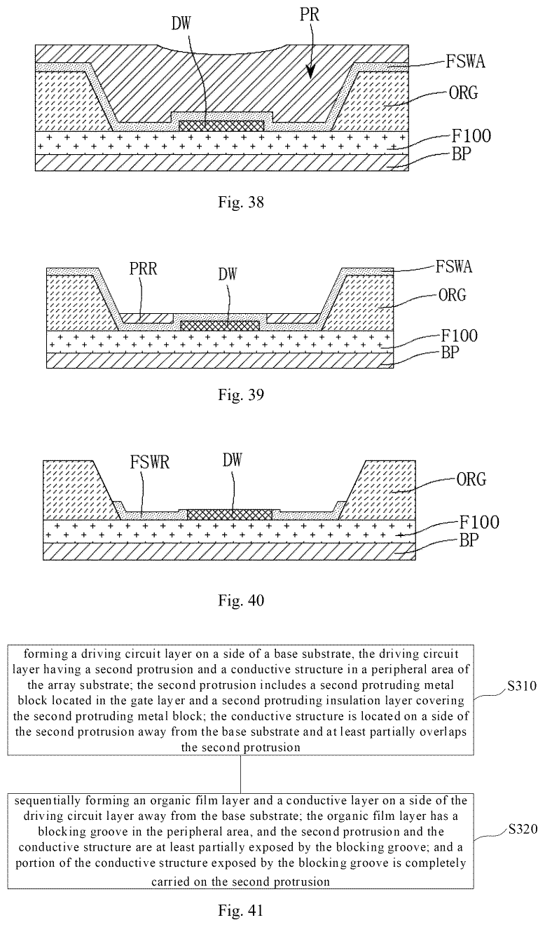

At step S021, referring to FIG. 37-1, a base substrate BP, a driving circuit layer F100 and an organic film layer ORG are prepared in sequence; the organic film layer ORG is provided with a blocking groove BG in a peripheral area BB, the driving circuit layer F100 is provided with a conductive structure DW in the peripheral area BB, and at least a portion of the conductive structure DW is exposed to the blocking groove BG, e.g., the conductive structure DW is entirely located in the blocking groove BG. At step S022, referring to FIG. 37-2, a conductive material layer FSWA is formed on a surface of the organic film layer ORG away from the base substrate BP. Then, referring to FIGS. 38 to 40, the conductive material layer FSWA is patterned by a photolithography process. Specifically, at step S023, referring to FIG. 38, a photoresist PR is coated on a side of the conductive material layer FSWA away from the base substrate BP. The photoresist PR fills the blocking groove BG; due to the fluidity of the photoresist, a thickness of a portion of the photoresist PR between the conductive structure DW and an edge of the blocking groove BG is the largest. At step S024, referring to FIG. 39, the photoresist PR is exposed and developed. Portions of the photoresist PR between edges of the blocking groove BG and the conductive structure DW cannot be sufficiently exposed and thus are remained, and the remained photoresist PRR may shield and protect the conductive material layer FSWA therebelow (on a side of the remained photoresist PRR close to the base substrate BP). At step S025, referring to FIG. 40, during patterning the conductive material layer FSWA by etching, the conductive material shielded by the remained photoresist PRR may not be sufficiently etched and thus is remained, and the remained conductive material FSWR may cause a short-circuit between two adjacent conductive structures DW.

Similarly, the inventor tried to eliminate the remained photoresist by an overexposure to alleviate the short-circuit defect, but found that the overexposure may greatly prolong the exposure time and affect the exposure beat, which may largely affect the throughput, thereby increasing the cost of the array substrate ARR. In addition, the inventor also found that as the size of each structure in the array substrate ARR is continuously reduced, the overexposure solution is more and more restricted by the process capability of the exposure machine.

In order to solve this short-circuit failure, referring to FIG. 41, in a third solution provided in the embodiment of the present disclosure, the array substrate ARR of the embodiment of the present disclosure may be manufactured by using the following method shown in steps S310 to S320.

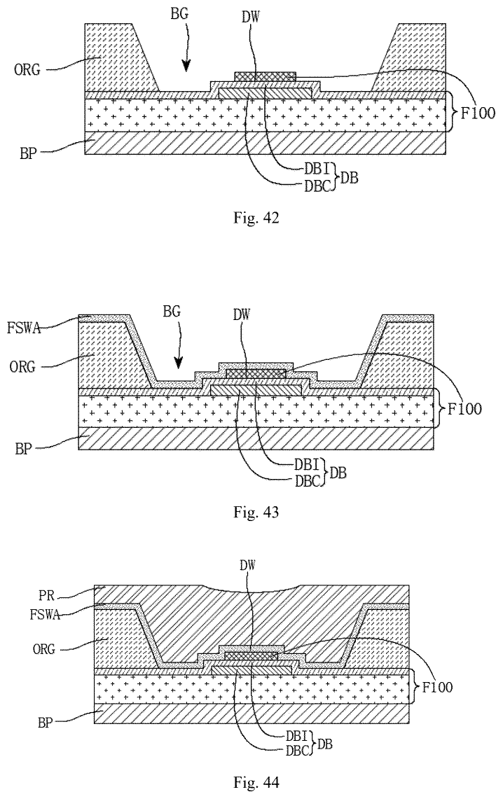

At step S310, referring to FIG. 42, a driving circuit layer F100 is formed on a side of a base substrate BP, the driving circuit layer F100 having a second protrusion DB and a conductive structure DW in a peripheral area BB of the array substrate ARR; the second protrusion DB includes a second protruding metal block DBC located in the gate layer GT and a second protruding insulation layer DBI covering the second protruding metal block DBC such that the second protrusion DB is formed into a mesa structure (i.e., a convex structure) protruding upward. The conductive structure DW is located on a side of the second protrusion DB away from the base substrate BP and at least partially overlaps the second protrusion DB.

At step S320, referring to FIGS. 42 to 46, an organic film layer ORG and a conductive layer FSW are sequentially formed on a side of the driving circuit layer F100 away from the base substrate BP; the organic film layer ORG has a blocking groove BG in the peripheral area BB, and the second protrusion DB and the conductive structure DW are at least partially exposed by the blocking groove BG; and a portion of the conductive structure DW exposed by the blocking groove BG is completely carried on the second protrusion DB. In other words, the portion of the conductive structure DW exposed by the blocking groove BG is completely located on the mesa structure formed by the second protrusion DB.

During forming the conductive layer FSW, since a step formed by the second protrusion DB exists between the conductive structure DW and a bottom of the blocking groove BG, the conductive material on the step can be sufficiently etched, and thus even if the conductive material is remained at edges of the second protrusion DB and the blocking groove BG, the conductive material cannot be connected with the conductive structure DW, and short-circuit between the conductive structures DW can be avoided. In addition, even if the conductive material, which is on the step and adjacent to the conductive structure DW, is unexpectedly not sufficiently etched, the remained conductive material can not be continuous at the edge of the second protrusion DB due to a height difference at the the edge of the second protrusion DB, which further reduces the risk of short-circuit between the conductive structures DW due to the remained conductive material.

In an example, a gap exists between an edge of the portion of the conductive structure DW exposed by the blocking groove BG and an edge of the second protrusion DB. Exemplarily, referring to FIG. 42, the conductive structure DW and the second protrusion DB are completely located within the blocking groove BG, and the conductive structure DW has a size smaller than that of the second protrusion DB.

In an example, the conductive layer FSW includes, within the blocking groove BG, a conductive material between edges of the second protrusion DB and the edges of the blocking groove BG, the conductive material being isolated from the conductive structure DW.

In an example, the organic film layer ORG and the conductive layer FSW are prepared as a part of the electrode composite layer F200. In other words, in the step S320, the electrode composite layer F200 is prepared on a side of the driving circuit layer F100 away from the base substrate BP. The electrode composite layer F200 includes the organic film layer ORG and the conductive layer FSW located on a side of the organic film layer ORG away from the base substrate BP

In an example, the step S320 may include steps S331 to S335.

At step S331, referring to FIG. 42, the organic film layer ORG is formed on the side of the driving circuit layer F100 away from the base substrate BP; the organic film layer ORG has the blocking groove BG in the peripheral area BB, and the second protrusion DB and the conductive structure DW are at least partially exposed by the blocking groove BG; and the portion of the conductive structure DW exposed by the blocking groove BG is completely carried on the second protrusion DB.

At step S332, referring to FIG. 43, a conductive material layer FSWA is formed on the side of the organic film layer ORG away from the base substrate BP, the conductive material layer FSWA covering the organic film layer ORG and the blocking groove BG. The conductive material layer FSWA covers the second protrusion DB and the conductive structure DW within the blocking groove BG.

At step S333, referring to FIG. 44, a photoresist PR is coated on a side of the conductive material layer FSWA away from the base substrate BP, and the photoresist PR fills the blocking groove BG. Referring to FIG. 44, a thickness of a portion of the photoresist PR above the second protrusion DB is reduced due to the elevation of the second protrusion DB.

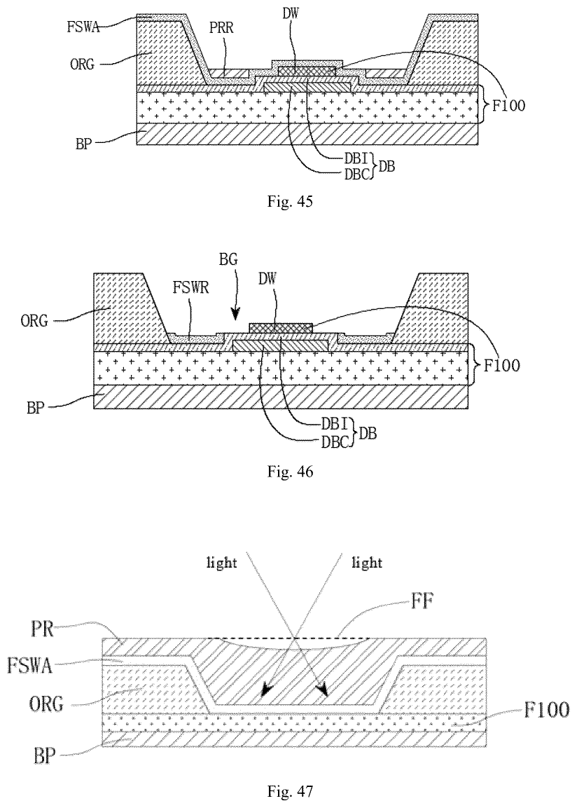

At step S334, referring to FIG. 45, the photoresist PR is exposed and developed. The portion of the photoresist PR in the blocking groove BG is reduced in thickness due to the elevation of the second protrusion DB and thus can be sufficiently exposed, and is not easily remained. Between the second protrusion DB and the edges of the blocking groove BG, there may be remained photoresist PRR that does not cover the second protrusion DB.

At step S335, the conductive material layer FSWA is etched to form a desired structure and form a conductive layer FSW; and then the photoresist is removed. In this process, referring to FIG. 46, between the edges of the blocking groove BG and the second protrusion DB, the conductive material is not sufficiently etched due to shielding of the remained photoresist, so that there remained a conductive material FSWR between the edges of the blocking groove BG and the second protrusion DB. However, the remained conductive material FSWR is isolated from the conductive structure DW by the second protrusion DB, thereby preventing the conductive structures DW from being short-circuited by the remained conductive material FSWR.

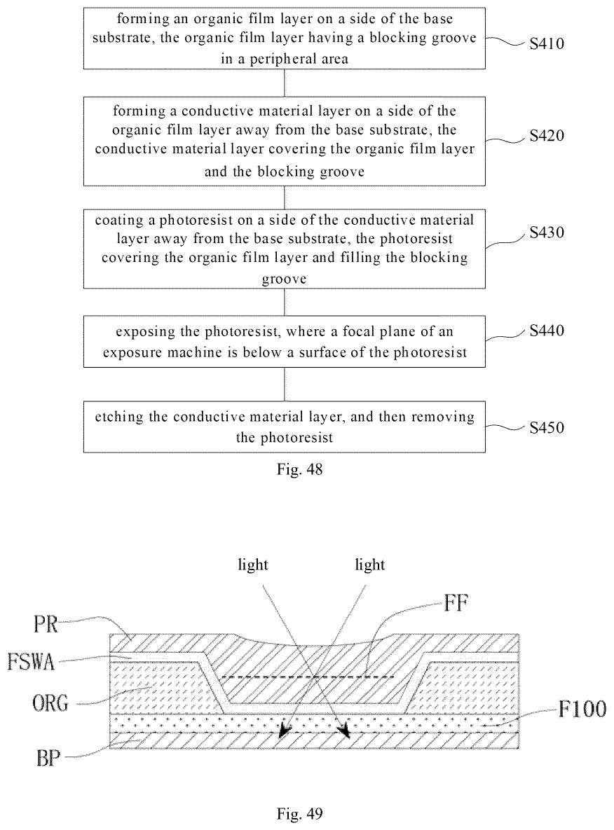

In order to solve this short-circuit failure, referring to FIG. 48, in a fourth solution provided in an embodiment of the present disclosure, the array substrate ARR of the embodiment of the present disclosure may be manufactured by using the following method shown in steps S410 to S450.

At step S410, referring to FIGS. 49 to 51, an organic film layer ORG is formed on a side of the base substrate BP, the organic film layer ORG having a blocking groove BG in a peripheral area BB.

At step S420, referring to FIGS. 49 to 51, a conductive material layer FSWA is formed on a side of the organic film layer ORG away from the base substrate BP, the conductive material layer FSWA covering the organic film layer ORG and the blocking groove BG.

At step S430, referring to FIGS. 49 to 51, a photoresist PR is coated on a side of the conductive material layer FSWA away from the base substrate BP, the photoresist PR covering the organic film layer ORG and filling the blocking groove BG.

At step S440, referring to FIGS. 49 to 51, the photoresist PR is exposed, where a focal plane FF of an exposure machine is below a surface of the photoresist PR

At step S450, the conductive material layer FSWA is etched, and then the photoresist is removed.

Referring to FIG. 47, in the related art, the focal plane FF of the exposure machine is generally on an upper surface of the photoresist (a surface of the photoresist away from the base substrate BP). In the method according to the embodiment of the present disclosure, the focal plane FF of the exposure machine is moved downward, so that an exposure degree of the photoresist PR at the bottom of the blocking groove BG can be increased, and thus the photoresist PR at the bottom within the blocking groove BG can be sufficiently exposed without increasing the exposure intensity (for example, increasing the intensity of light for exposure or prolonging an exposure time), and a pattern of the shallow photoresist (for example, the photoresist on the organic film layer ORG) is not adversely affected. Therefore, the photoresist PR at the bottom within the blocking groove BG is sufficiently exposed, an accuracy of a pattern of the photoresist subjected to development is improved, and an accuracy of a pattern of the conductive material layer FSWA subjected to patterning is further improved, the conductive material unexpectedly ramined in the blocking groove BG after the conductive material layer FSWA is patterned can be reduced or avoided, and the short-circuit failure in the blocking groove BG can be further avoided.

In an example, at step S450, referring to FIG. 49, in the blocking groove BG, a distance between the focal plane FF of the exposure machine and the bottom of the blocking groove BG is not more than half of a maximum thickness of the photoresist in the blocking groove BG to ensure sufficient exposure of the photoresist at the bottom of the blocking groove BG.

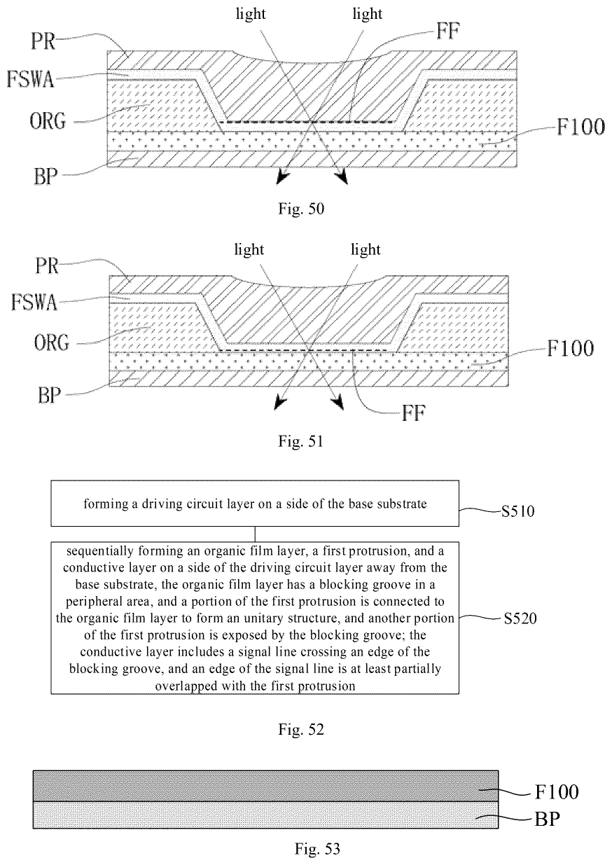

In another example, at step S450, referring to FIG. 50 or FIG. 51, in the blocking groove BG, the focal plane FF of the exposure machine is near or below a bottom surface of the photoresist. Thus, a design of a mask plate used for exposure is facilitated.

In an implementation, the driving circuit layer F100 may be located on a side of the conductive material layer FSWA away from the base substrate BP, or between the conductive material layer FSWA and the base substrate BP, which is not particularly limited in the present disclosure. In the examples of FIGS. 49 to 51, the driving circuit layer F100 is located between the conductive material layer FSWA and the base substrate BP. Then, before the step S410, it is also possible to first prepare the driving circuit layer F100 on the base substrate BP, and then prepare the organic film layer ORG and the conductive material layer FSWA on a side of the driving circuit layer F100 away from the base substrate BP. In other implementations of the present disclosure, the organic film layer ORG and the conductive material layer FSWA may be prepared first, for example, a pixel electrode or a common electrode of the array substrate ARR is prepared first, and then the driving circuit layer F100 is prepared.

In an implementation of the present disclosure, the display panel PNL further includes a cover plate CF which is combined with and arranged opposite to the array substrate ARR, and a frame sealing adhesive provided between the array substrate ARR and the cover plate CF; the frame sealing adhesive covers the blocking groove BG; the driving circuit layer F100 has a conductive line overlapping with the frame sealing adhesive in the peripheral area BB, and the conductive line is designed as a mesh.

In order to solve this short-circuit failure, referring to FIG. 52, in a fifth solution provided in an embodiment of the present disclosure, the array substrate ARR of the embodiment of the present disclosure may be manufactured by the following method shown in steps S510 to S520.

At step S510, referring to FIG. 53, a driving circuit layer F100 is formed on a side of the base substrate BP.

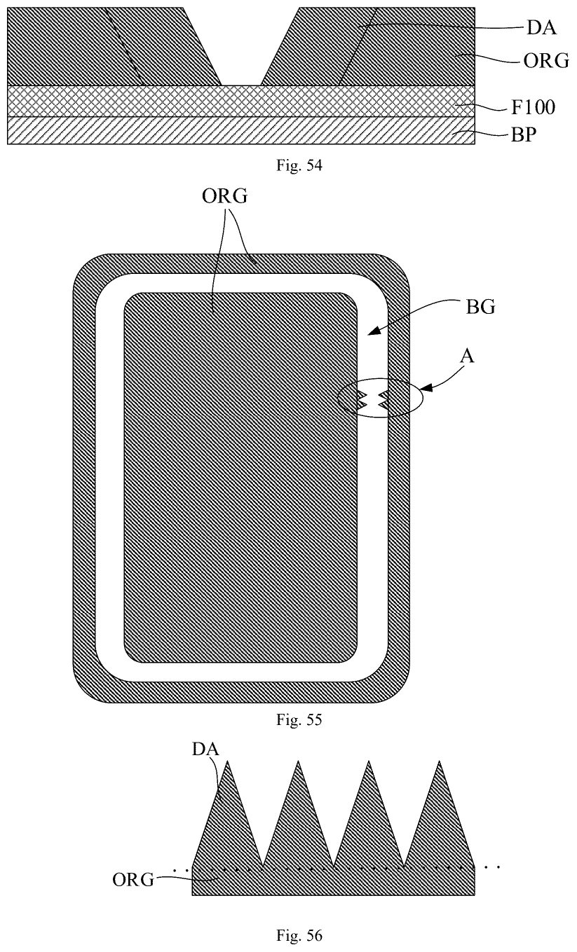

At step S520, referring to FIGS. 54 to 61, an organic film layer ORG, a first protrusion DA, and a conductive layer FSW are sequentially formed on a side of the driving circuit layer F100 away from the base substrate BP. The organic film layer ORG has a blocking groove BG in a peripheral area BB, and a portion of the first protrusion DA is connected to the organic film layer ORG to form an integral structure (i.e., an unitary structure), and another portion of the first protrusion DA is exposed by the blocking groove BG. The conductive layer FSW includes a signal line SW crossing edges of the blocking groove BG, and an edge of the signal line SW is at least partially overlapped with the first protrusion DA.

In an example, the organic film layer ORG and the conductive layer FSW are prepared as a part of the electrode composite layer F200. In other words, in the step S520, the electrode composite layer F200 is prepared on the side of the driving circuit layer F100 away from the base substrate BP. The electrode composite layer F200 includes the organic film layer ORG and the conductive layer FSW located on a side of the organic film layer ORG away from the base substrate BP.

In an example, the step S520 may include steps S521 to S526.

At step S521, referring to FIGS. 54 to 56, the first protrusion DA and the organic film layer ORG having the blocking groove BG in the peripheral area BB are formed on the side of the driving circuit layer F100 away from the base substrate BP. The first protrusion DA and the organic film layer ORG are of an unitary structure, and a portion of the first protrusion DA is exposed by the blocking groove BG. In other words, the first protrusion DA is located at a lower edge (an edge close to the base substrate) of the blocking groove BG.

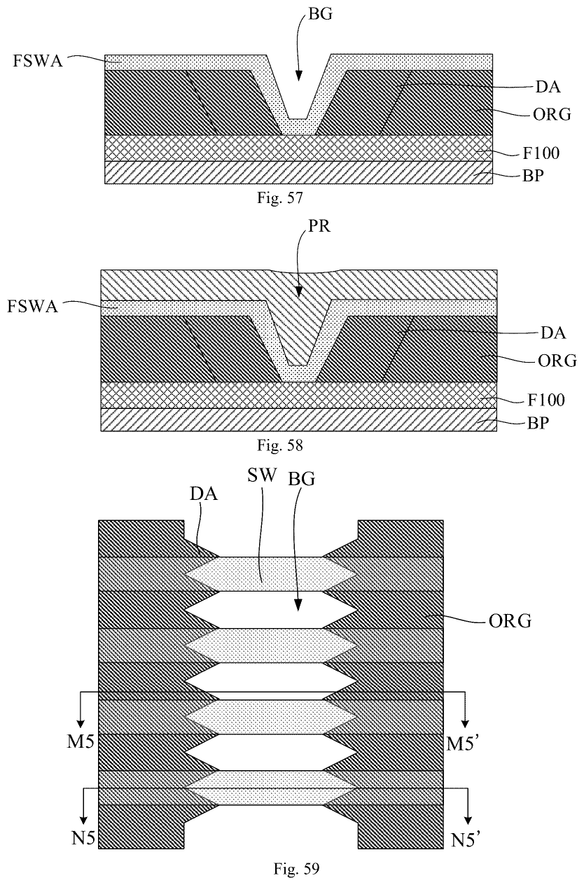

At step S522, referring to FIG. 57, a conductive material layer FSWA is formed on a side of the organic film layer ORG away from the base substrate BP, the conductive material layer FSWA covering the organic film layer ORG and the blocking groove BG.

At step S523, referring to FIG. 57, a photoresist PR is coated on a side of the conductive material layer FSWA away from the base substrate BP, and the photoresist PR fills the blocking groove BG.

At step S524, the photoresist PR is exposed and developed.

At step S525, the conductive material layer FSWA is etched to form a desired structure, for example, a desired signal line SW. In the process, at a portion, that is elevated by the first protrusion DA, of an edge area of the blocking groove BG, the conductive material is not shielded by remained photoresist and thus can be sufficiently etched, so that an accuracy of a pattern of the signal line SW is ensured, and the short-circuit between the signal lines SW caused by the remained conductive material between the signal lines SW is avoided.

At step S526, the photoresist PR is removed.

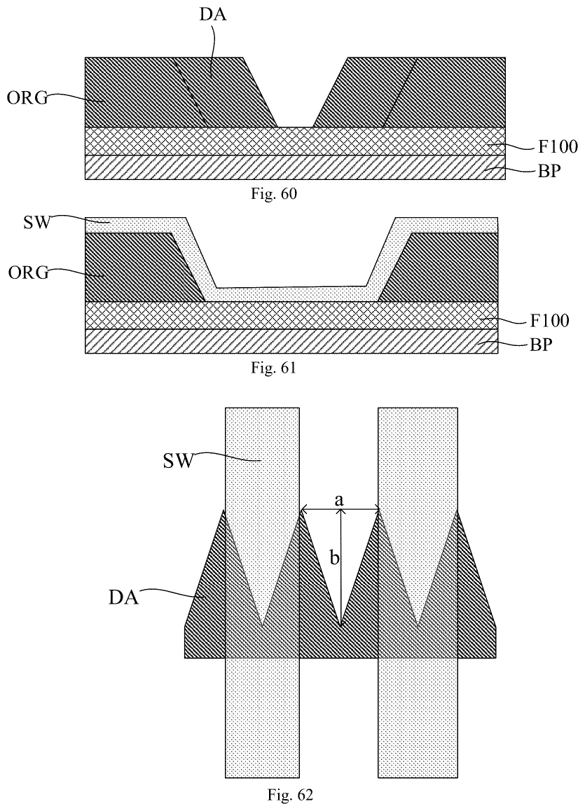

In the embodiment of the present disclosure, the first protrusion can be prepared on the driving circuit layer by adjusting the mask plate for the organic film layer. The first protrusion is located in the blocking groove, and at least part of the first protrusion is in contact with the organic film layer. For example, in some examples, the first protrusion and the organic film layer are formed as a single piece, in which case the first protrusion protrudes from a sidewall of the organic film layer. At least a portion of the edge of the signal line overlaps the first protrusion, as shown in FIGS. 59 to 60.

In some implementations, a plurality of first protrusions are respectively provided on two edges of the blocking groove, and a gap is formed between every two adjacent first protrusions. For convenience of description, a gap between two adjacent first protrusions on one of the edges of the blocking groove is referred to as a first gap, and a gap between two adjacent first protrusions on the other of the edges of the blocking groove is referred to as a second gap. In an example, first gaps and second gaps are provided in one-to-one correspondence, and the first protrusions provided on both edges of the blocking groove are provided in one-to-one correspondence. In this case, every two adjacent signal lines are spaced apart by at least one first gap/second gap. During forming the conductive material layer, the conductive material layer covers the first protrusion, so that a step difference (height difference) between the conductive material layer on the first protrusion and a surface of the organic film layer located in the display area is smaller. Referring to FIG. 58, compared to the related art, after the photoresist is coated, the thickness of the photoresist on the first protrusion is reduced and the photoresist is not easily remained during exposure and development. Therefore, the conductive material can not be remained in a portion of the gap between two adjacent signal lines on the first protrusion, and thus the short-circuit between the signal lines is eliminated. Therefore, the gap between the signal lines is overlapped with the first protrusion.

In an implementation, referring to FIGS. 59 and 62, each signal line covers at least one first gap/second gap, i.e., each signal line is overlapped with at least two adjacent first protrusions provided on a same edge of the blocking groove. For example, in an example, each signal line covers one first gap/second gap, that is, each signal line overlaps two adjacent first protrusions provide on a same edge of the blocking groove. In this case, in an example, orthographic projections of two edges of the signal line on the base substrate respectively overlap with orthographic projections of first central lines of the two adjacent first protrusions on the base substrate; the first central line of the first protrusion is a straight line which is in a direction in which the display area points to the peripheral area and penetrates through a center of a position of the first protrusion at which the first protrusion is connected with the edge of the blocking groove. For example, in a case where an orthographic projection of the first protrusion on the base substrate is an isosceles triangle, heights of two adjacent triangles are respectively coincide with two edges of one signal line, as shown in FIG. 62.

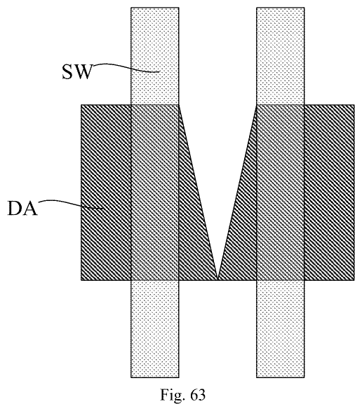

In an implementation, the signal line is not overlapped with the gap between two adjacent first protrusions, that is, the signal line is only located at a position corresponding to the first protrusion, as shown in FIG. 63. In an example, an orthographic projection of a portion of the first protrusion on the base substrate is located between orthographic projections of two adjacent signal lines on the substrate. In this case, the conductive material cannot be remained at a portion, which is located on the first protrusion, of the gap between two adjacent signal lines, thus the short-circuit failure between the signal lines is eliminated. Therefore, the gap between the signal lines is overlapped with the first protrusion.

In some implementations, a plurality of first protrusions are respectively provided on two edges of at least a partial region of the blocking groove. For the first protrusions provided on a same edge of the blocking groove, an orthographic projection of the gap between two adjacent first protrusions on the base substrate is a first pattern. In the direction in which the display area points to the peripheral area, a width of a portion of the first pattern close to the display area is not smaller than a width of a portion of the first pattern away from the display area. For example, in an example, the first pattern is a triangle, and for example may be specifically an isosceles triangle; correspondingly, the orthographic projection of the first protrusion on the base substrate is a triangle, and in a case where the first pattern is an isosceles triangle, the orthographic projection of the first protrusion on the base substrate is an isosceles triangle. For another example, the first pattern is a trapezoid, and specifically, the first pattern may be an isosceles trapezoid; correspondingly, the orthographic projection of the first protrusion on the base substrate is a trapezoid, and in a case where the first pattern is an isosceles trapezoid, the orthographic projection of the first protrusion on the base substrate is an isosceles trapezoid.

In an example, referring to FIG. 62, for the first protrusions provided on the same edge of the blocking groove, a maximum pitch between two adjacent first protrusions is a, a height of the first pattern is b, and b≥3a. For example, in a case where the first pattern is a triangle, the maximum pitch between two adjacent first protrusions is a length of a base of the first pattern. In this case, the height of the triangle of the first pattern is not less than 3 times the length of the base of the triangle. For example, the height of the triangle of the first pattern is b, a value of b is more than 75 μm, the length of the base of the triangle of the first pattern is a, and a value of a is more than 10 μm. Referring to FIG. 62, by reasonably setting a size of the first protrusion, even if the conductive material is remained during forming the signal lines, the remained conductive material is only located at a sharp corner formed by portions of the adjacent first protrusions close to the display area, and the adjacent signal lines are not overlapped with these portions, so that the short-circuit between the adjacent signal lines can be effectively avoided.

In some implementations, a certain gap is formed between the first protrusions provided on the two edges of the blocking groove. That is, the first protrusions provided on the two edges of the blocking groove are independent from each other, so that the intensity of light irradiated to the frame sealing adhesive is improved, and the speed of curing the photoresist is improved. An embodiment of the present disclosure further provides a display device including any one of the display panels described in the above embodiments of the display panels. The display device may be a smartphone screen, a smart watch screen, or any other type of display device. Since the display device has any one of the display panels described in the above embodiments of the display panel, the display device has the same beneficial effects, which are not repeated herein.

In an implementation of the present disclosure, referring to FIG. 1, the display panel PNL is a liquid crystal display panel, and the display device further includes a backlight module BLU located at a back side of the liquid crystal display panel. Thus, the display device is a transmissive liquid crystal display device.

It should be noted that although the steps of the method for manufacturing the array substrate in the present disclosure are described in the drawings in a particular order, which does not require or imply that the steps must be performed in this particular order or that all of the described steps must be performed to achieve a desired result. Additionally or alternatively, certain steps may be omitted, multiple steps may be combined into one step to be performed, and/or one step is decomposed into multiple steps to be performed, etc.

Other embodiments of the present disclosure will be apparent to those skilled in the art from consideration of the specification and practice of the invention disclosed herein. The present disclosure is intended to cover any variations, uses, or adaptive changes of the present disclosure, which follow the general principles of the present disclosure and include common knowledge or customary technical means in the art not disclosed herein. The specification and embodiments are only considered illustrative, and the true scope and spirit of the present disclosure are indicated by the accompanying claims.

1. An array substrate, comprising a base substrate, a driving circuit layer, an organic film layer and a conductive layer which are sequentially stacked; wherein, at least part of the organic film layer in a peripheral area is provided with at least one blocking groove;
the array substrate further comprises a first protrusion, and at least part of the first protrusion is located in each blocking groove; and at least part of the first protrusion is in contact with the organic film layer; the conductive layer comprises a signal line crossing an edge of the blocking groove, and an edge of the signal line is at least partially overlapped with the first protrusion.

2. The array substrate of claim 1, wherein in at least a partial region of the blocking groove, two edges of the blocking groove each are provided with a plurality of first protrusions;
for the first protrusions on a same edge of the blocking groove, an orthographic projection of a gap between two adjacent first protrusions on the base substrate is a first pattern; in a direction that a display area points to the peripheral area, a width of a portion of the first pattern close to the display area is not smaller than a width of a portion of the first pattern away from the display area.

3. The array substrate of claim 2, wherein the first pattern comprises an isosceles triangle or an isosceles trapezoid.

4. The array substrate of claim 2, wherein for the first protrusions provided on a same edge of the blocking groove, a maximum pitch between two adjacent first protrusions is a, a height of the first pattern is b, and b≥3a.

5. The array substrate of claim 2, wherein the first protrusions provided on one of the two edges of the blocking groove are in a one-to-one correspondence with the first protrusions provided on one of the two edges of the blocking groove, and two first protrusions corresponding to each other and respectively provided on the two edges of the blocking groove are spaced apart from each other by a distance.

6. The array substrate of claim 2, wherein two edges of a single signal line are respectively overlapped with two adjacent first protrusions, and the signal line covers a gap between the two adjacent first protrusions.

7. The array substrate of claim 6, wherein for the first protrusions provided on a same edge of the blocking groove, an orthographic projection of each first protrusion on the base substrate is a second pattern, first patterns and second patterns are alternately arranged, and the first pattern has a shape which coincides with a shape of a vertically inverted second pattern.

8. The array substrate of claim 6, wherein orthographic projections of two edges of the signal line on the base substrate are respectively overlapped with orthographic projections of first central lines of two adjacent first protrusions on the base substrate; the first central line of the first protrusion is a straight line which is in the direction in which the display area points to the peripheral area and penetrates through a center of a position of the first protrusion at which the first protrusion is connected with the edge of the blocking groove.

9. The array substrate of claim 2, wherein in at least a partial region of the blocking groove, two edges of the blocking groove each are provided with a plurality of first protrusions; and
two edges of a single signal line are respectively overlapped with two adjacent first protrusions, and the signal line is not overlapped with a gap between the two adjacent first protrusions.

10. The array substrate of claim 1, wherein the first protrusion and the organic film layer are of an unitary structure.

11. The array substrate of claim 1, wherein the at least one blocking groove comprises a plurality of blocking grooves, and at least part of the blocking grooves are sequentially arranged around the display area, or
at least one of the blocking grooves are continuous, or
at least one of the blocking grooves comprises a plurality of sub-grooves spaced apart from each other.

12. (canceled)

13. (canceled)

14. The array substrate of claim 1, wherein the driving circuit layer comprises the first protrusion in the peripheral area of the array substrate; the first protrusion comprises a first protruding metal block located in at least one of a source-drain metal layer or a gate layer and a first protruding insulation layer covering the first protruding metal block; and
the organic film layer comprises the blocking groove in the peripheral area, and a portion of the first protrusion is covered by the organic film layer and the other portion of the first protrusion is exposed by the blocking groove.

15. The array substrate of claim 14, wherein in at least a partial region of the blocking groove, two edges of the blocking groove each are provided with a plurality of first protrusions; and two edges of a single signal line are respectively overlapped with two adjacent first protrusions, and the signal line covers a gap between the two adjacent first protrusions, or
in at least a partial region of the blocking groove, two edges of the blocking groove each are provided with one first protrusion; and the signal line intersects with the first protrusions, or
a plurality of first protrusions are provided in at least a partial region of the blocking groove; two ends of any one of the first protrusions are respectively covered by the organic film layer on two sides of the blocking groove; two edges of each of at least part of the signal lines are respectively overlapped with two adjacent first protrusions, and the signal line covers a gap between the two adjacent first protrusions, or
in at least a partial region of the blocking groove, one first protrusion is provided, and both sides of the first protrusion are covered by the organic film layer on both sides of the blocking groove; a portion of at least part of the signal lines at a bottom of the blocking groove is carried on the first protrusion.

16. (canceled)

17. (canceled)

18. (canceled)

19. The array substrate of claim 14, wherein the driving circuit layer comprises a ground line in the peripheral area, and the ground line at least partially overlaps the blocking groove; and
at least part of the first protruding metal blocks is a part of the ground line, or
a portion of the signal line which crosses the edge of the blocking groove is not overlapped with the ground line.

20. (canceled)

21. The array substrate of claim 14, wherein a dimension of a portion of the first protrusion covered by the organic film layer in a direction perpendicular to an extending direction in which the blocking groove extends is not less than 2 μm, or
a height of the first protrusion protruding from the bottom of the blocking groove is not less than 10% of a depth of the blocking groove.

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. An array substrate, comprising a base substrate, a driving circuit layer, an organic film layer and a conductive layer which are sequentially stacked;
the driving circuit layer comprises a transfer line in a peripheral area of the array substrate, and the transfer line is located in at least one of a source-drain metal layer or a gate layer;
the organic film layer is provided with a blocking groove and via holes exposing the transfer line in the peripheral area; at least part of the transfer line crosses the blocking groove; the conductive layer comprises a signal line that is cut by edges of the blocking grooves, and two adjacent ends of portions of the signal line cut by the edges of the blocking groove are electrically connected to each other by the transfer line; and the signal line is connected with the transfer line through the via holes.

39. The array substrate of claim 38, wherein at least part of the transfer line crosses the blocking groove and both ends of the transfer line are exposed by the via holes;
at least part of the signal line are cut by the blocking groove, and two adjacent ends of the signal line are connected with two ends of the transfer line through the via holes, respectively, and wherein
the conductive layer further comprises, in the blocking groove, a conductive material at the edge of the blocking groove, and the conductive material is disconnected from the signal line.

40. (canceled)

41. (canceled)

42. An array substrate, comprising a base substrate, a driving circuit layer, an organic film layer and a conductive layer which are sequentially stacked; wherein
the driving circuit layer comprises a second protrusion and a conductive structure in the peripheral area of the array substrate; the second protrusion comprises a second protruding metal block located in the gate layer and a second protruding insulation layer covering the second protruding metal block; the conductive structure is located on a side of the second protrusion away from the base substrate and at least partially overlapped with the second protrusion; and
the organic film layer is provided with a blocking groove in the peripheral area, and the second protrusion and the conductive structure are at least partially exposed by the blocking groove; and a portion of the conductive structure exposed by the blocking groove is completely carried on the second protrusion.

43. The array substrate of claim 42, wherein an edge of the portion of the conductive structure exposed by the blocking groove is spaced apart from an edge of the second protrusion by a gap, and wherein
the conductive layer comprises, in the blocking groove, a conductive material between the edge of the second protrusion and an edge of the blocking groove, the conductive material being disconnected from the conductive structure.

44. (canceled)

45. (canceled)

46. (canceled)

47. (canceled)

48. A display panel, comprising the array substrate of claim 1.

49. (canceled)
